(19) United States
(12) Patent Application Publication
(10) Pub. No.: US 2013/0052826 A1
(43) Pub. Date: Feb. 28, 2013

(54) High Aspect Ratio Grid for Phase Contrast X-ray Imaging and Method of Making the Same

(71) Applicants: Mark Nepomnishy, San Jose, CA (US); Shinya Sugimoto, San Jose, CA (US); Yasuhisa Kaneko, Ashigarakami-Gun (JP)

(72) Inventors: Mark Nepomnishy, San Jose, CA (US); Shinya Sugimoto, San Jose, CA (US); Yasuhisa Kaneko, Ashigarakami-Gun (JP)

(73) Assignee: FUJIFILM CORPORATION, Tokyo (JP)

(21) Appl. No.: 13/221,702

(22) Filed: Aug. 30, 2011

(51) Int. Cl. H01L 21/311

(52) U.S. Cl. 438/694; 257/E21.249

(57) ABSTRACT

Semiconductor substrates with high aspect ratio recesses formed therein are described. The high aspect ratio recesses have bottom surface profile characteristics that promote formation of initial growth sites of plated metal as compared to the side surfaces of the recesses. Processes for making and plating the recesses are also disclosed. The metal-plated high aspect ratio recesses can be used as X-ray gratings in Phase Contrast X-ray imaging apparatuses.

### TECHNICAL FIELD

This specification relates to processing of high-aspect ratio surface features in semiconductor substrates.

### BACKGROUND

Phase contrast x-ray imaging techniques are used in investigating the inner structures of objects such as biological tissue samples. In one technique, the imaging apparatus includes two gratings placed between a sample object and an image detector. The first grating is just downstream of the sample object. The second grating is a grating located between the first grating and the image detector. In some implementations, a third grating is placed between the sample object and an X-ray radiation source to create an array of spatially coherent line sources that irradiate the sample object.

The basic structure of the second grating includes a periodic array of alternating X-ray transmitting features and X-ray absorbing features in a plane transverse to the X-ray propagation direction. The pitch of the periodic array can be in the range of a few microns. The depths of the X-ray transmitting and X-ray absorbing features in the direction of X-ray propagation determine the imaging contrast produced by the grating. A workable depth for an X-ray absorbing feature made of gold can be at least 10-15 microns, leading to about 25% contrast. A higher imaging contrast typically requires a greater depth for the X-ray absorbing features. Thus, a high depth-to-width aspect ratio is needed for the X-ray transmitting features and the X-ray absorbing features in the second grating.

A conventional technique for forming the second grating in the imaging apparatus is by first creating deep, narrow, and tightly spaced linear recesses in the surface of a semiconductor substrate, and then filling the linear recesses with gold by electroplating. The technique works theoretically, but in practice, filling a micro-sized, high depth-to-width aspect ratio recess in a semiconductor substrate is a challenging task. Non-uniform fillings can create uneven absorptions of the incident X-rays and cause deteriorated imaging performance of the second grating.

U.S. Publication No. 2009/0092227 “Interferometer for Quantitative Phase Contrast Imaging and Tomography with an incoherent polychromatic X-ray Source” by David et al. describes an example interferometer for obtaining quantitative phase contrast images. U.S. Publication No. 2010/0061508 “Radiation Phase Image Radiographing Apparatus” by Takahashi describes a radiation phase image radiographing apparatus and example component gratings. Japanese Laid-Open patent JP 2010-185728 describes a process for making high aspect ratio recesses in a semiconductor substrate.

### SUMMARY

This specification describes technologies related to electroplating micro-sized, high-aspect ratio recesses in a semiconductor substrate.

When electroplating a high depth-to-width aspect ratio recess in the surface of a semiconductor substrate using conventional methods, some of the plating metal ions can make contact with the sidewalls of the recess and form initial growth sites for the plated metal before the regions below the growth sites are completely filled by the plated metal. As the plated metal continues to accumulate at the initial growth sites formed on the sidewalls, it may block the regions of the recess below those initial growth sites from further contact with the plating metal ions. The blockage can leave voids in various regions in the plated metal formed inside the recess, especially in the bottom portion of the recess.

An application of electroplating micro-sized high depth-to-width aspect ratio recesses is in making a high-contrast X-ray grating. An array of closely spaced, deep and narrow linear recesses can be formed in a semiconductor substrate, and then the linear recesses can be filled with a strong X-ray absorbing metal, such as gold, by electroplating. The resulting structure includes alternating thin layers of semiconductor material (i.e., the X-ray transmitting features) and gold (i.e., the X-ray absorbing features) standing perpendicularly on a planar semiconductor backing.

The depth and uniformity of the X-ray absorbing metal filled inside the linear recesses affect the performance of the grating. For example, voids existing along the depths of the X-ray absorbing features (e.g., Au) allow more X-rays to leak through to the backside of the grating and reduce the imaging contrast of the grating due to insufficient absorption.

As described in this specification, in order to solidly and uniformly fill the closely spaced, high depth-to-width aspect ratio recesses in a semiconductor substrate using electroplating techniques, steps are taken, either before or after the creation of the side surface(s) the recesses, to create surface profile characteristics on the bottom surfaces of the recesses such that the bottom surfaces become more favorable to the creation of initial growth sites for the plated metal, as compared to the side surfaces of the recesses.

In general, a rough surface texture with more and/or sharper protruding features on the bottom surface of a recess is more attractive to the plating metal ions than a smooth side surface. The rough surface texture can cause the bottom portion of the recess to be completely filled by the plated metal before the plating progresses upwards along the side surfaces of the recesses. Several techniques are described in this specification for creating high aspect ratio recesses having the rough surface textures and/or protrusions on the bottom surfaces.

In addition, on a semiconductor surface, a greater surface area in contact with a given volume of plating solution can lead to more opportunities for a metal ion to deposit on the surface and form an initial growth site for the plated metal. Therefore, when the bottom surface area of a recess is increased without altering the lateral dimensions of the recess (e.g., by bending the bottom surface away from the top opening of the recess), the likelihood that initial growth sites of the plated metal would form on the bottom surface would also be increased. As a result, the likelihood of voids occurring in the bottom portion of a recess is reduced. Techniques for creating a high-aspect ratio recess with a bottom surface that bends away from the plane in which the side surfaces of the recess intersect with the bottom surface are also described in this specification.

In one aspect, a process includes the steps of: forming a recess in a first surface of a semiconductor substrate, where the recess has one or more side surfaces, a bottom surface and a top opening, and where the forming includes creating surface profile characteristics on the bottom surface, the surface profile characteristics including an expanded surface area or a roughened surface texture that is operable to cause the bottom surface to provide a substantially more active plating area than the side surfaces do when the semiconductor substrate is exposed to plating metal ions in a plating environment; and exposing the semiconductor substrate having the recess to the plating environment, where respective initial growth sites of a plated metallic conductor form on the bottom surface of the recess and the plated metallic conductor fills the recess starting from the bottom surface and then up along the side surfaces of the recess.

In some implementations, the process further includes: before exposing the semiconductor substrate to the plating environment, applying an insulator coating on the first surface of the semiconductor substrate, the insulator coating partially covering the side surfaces of the recess, and leaving the bottom surface of the recess and bottom portions of the side surfaces adjacent to the bottom surface exposed.

In some implementations, the surface profile characteristics of the bottom surface of the recess are produced by a plurality of silicon grass formed on the bottom surface of the recess.

In some implementations, the process for forming the one or more recesses further includes: etching the first surface of the semiconductor substrate using a first etching process, where the etching using the first etching process forms the one or more side surfaces of the recess, and the one or more side surfaces formed by the first etching process terminate at a substantially flat and smooth end surface, and where the process for creating the surface profile characteristics on the bottom surface further includes: after the etching using the first etching process is completed, dry etching the substantially flat and smooth end surface in the recess using a second etching process, where the second etching process causes a plurality of protrusions to form on the substantially flat end surface, and the end surface with the plurality of protrusions serves as the bottom surface of the recess.

In some implementations, the first etching process is a Bosch process using a first etching recipe, the second etching process is a Bosch process using a second etching recipe, and the second etching recipe is operable to cause more particle deposition on the bottom surface of the recess than the first etching recipe does.

In some implementations, the first etching recipe includes a first concentration of C4F8 gas in a respective passivation gas mixture used in a respective passivation cycle of the first etching process, the second etching recipe includes a second concentration of C4F8 gas in a respective passivation gas mixture used in a respective passivation cycle of the second etching process, and the second concentration is greater than the first concentration.

In some implementations, the first etching recipe uses a first etching duration for a respective etching cycle of the first etching process, the second etching recipe uses a second etching duration for a respective etching cycle of the second etching process, and the second etching duration is shorter than the first etching duration.

In some implementations, the first etching recipe uses a first passivation duration for a respective passivation cycle of the first etching process, the second etching recipe uses a second passivation duration for a respective passivation cycle of the second etching process, and the second passivation duration is longer than the first passivation duration.

In some implementations, the process for forming the recess in the first surface of the semiconductor substrate further includes: forming a mask layer on the first surface of the semiconductor substrate, the mask layer having an opening that define a location and lateral dimensions of the recess to be formed in the first surface of the semiconductor substrate; anisotropically etching the first surface of the semiconductor substrate through the opening of the mask layer, the anisotropic etching forming a cavity in the first surface of the semiconductor substrate, an inner surface of cavity includes the surface profile characteristics of the bottom surface of the recess to be formed; and after the cavity has been formed in the first surface of the semiconductor substrate, anisotropically etching the inner surface of the cavity in a direction perpendicular to the top opening of the recess to be formed in the first surface of the semiconductor substrate, the anisotropic etching of the inner surface of the cavity producing the side surfaces of the recess and the bottom surface of the recess having the surface profile characteristics.

In some implementations, the semiconductor substrate is a silicon substrate, a top surface of the silicon substrate is aligned with the {100} crystal planes of the silicon substrate, wherein the recess is a linear recess having a length along the [011] direction of the silicon substrate.

In some implementations, the anisotropic etching to form the cavity is wet etching using a KOH or TMAH solution.

In some implementations, the anisotropic etching of the inner surface of the cavity is dry etching using a plasma etchant.

In some implementations, the bottom surface of the recess includes two planar facets along the {111} crystal planes of the silicon substrate, the two planar facets intersect along a straight line in the center of the bottom surface.

In some implementations, the semiconductor substrate is a silicon substrate, a top surface of the silicon substrate is aligned with the {110} crystal planes of the silicon substrate, wherein the recess is a linear recess having a length along the [211] direction of the silicon substrate.

In some implementations, the anisotropic etching to form the cavity is wet etching using a KOH or TMAH solution.

In some implementations, the anisotropic etching of the inner surface of the cavity uses a same wet etching method that formed the cavity.

In some implementations, the process for forming the recess in the first surface of the semiconductor substrate further includes: forming a photoresist layer on the first surface of the semiconductor substrate, the photoresist layer having a straight-walled opening that define a location and lateral dimensions of the recess to be formed in the first surface of the semiconductor substrate; annealing the photoresist layer such that the straight-walled opening morphs to an opening having inwardly curving sidewalls; etching the first surface of the semiconductor substrate through the opening having the inwardly curving sidewalls, the etching forming a cavity in the first surface of the semiconductor substrate, and an inner surface of cavity curving away from an opening of the cavity; and after the cavity has been formed in the first surface of the semiconductor substrate, etching the semiconductor substrate through the inner surface of the cavity in a direction perpendicular to the top opening of the cavity, the etching through the inner surface of the cavity producing the side surfaces of the recess and the bottom surface of the recess curving away from the top opening of the recess, and the curved bottom surface provides the expanded surface area of the bottom surface.

In some implementations, the semiconductor substrate includes an oxide layer and a silicon layer.

In some implementations, the cavity is formed in the oxide layer, and the recess is formed in the silicon layer below the oxide layer.

In some implementations, etching the semiconductor substrate through the inner surface of the cavity in a direction perpendicular to the top opening of the cavity is carried out using a Bosch process, and the oxide layer provides a mask layer for the Bosch process.

In some implementations, the process for forming the recess in the first surface of the semiconductor substrate further includes: forming a photoresist layer on the first surface of the semiconductor substrate; patterning the photoresist layer using a grayscale mask, the patterned photoresist layer having a thinner portion that define a location and lateral dimensions of the recess to be formed, and the thinner portion has thickness profile showing one or more protrusion above a baseline of the thinner portion; etching the first surface of the semiconductor substrate through the patterned photoresist layer, the etching forming a cavity in the first surface of the semiconductor substrate, and an inner surface of cavity includes one or more protrusions matching the thickness profile of the patterned photoresist layer; and after the cavity has been formed in the first surface of the semiconductor substrate, etching the semiconductor substrate through the inner surface of the cavity in a direction perpendicular to a top opening of the cavity, the etching through the inner surface of the cavity producing the side surfaces and the bottom surface of the recess, and bottom surface includes one or more protrusions that matching the one or more protrusions in the inner surface of the previously formed cavity.

In some implementations, the semiconductor substrate includes an oxide layer and a silicon layer.

In some implementations, the cavity is formed in the oxide layer, and the recess is formed in the silicon layer below the oxide layer.

In some implementations, etching the semiconductor substrate through the inner surface of the cavity in a direction perpendicular to the top opening of the cavity is carried out using a Bosch process, and the oxide layer provides a mask layer for the Bosch process.

In some implementations, the bottom surface of the recess includes a single pointy protrusion at the center of the bottom surface.

In some implementations, the bottom surface of the recess includes multiple randomly located protrusions.

In some implementations, the bottom surface of the recess includes a periodic array of protrusions.

In some implementations, the recess has an aspect ratio in a range of 10:1 to 100:1 between a width of the bottom surface and a depth of the recess.

In some implementations, the process forms a periodic array of recesses including the recess and fills each of the recesses with the plated metal conductor from the bottom up.

In some implementations, the recess has a depth of 30-200 microns along the one or more side surfaces, a width of 2-20 microns along the bottom surface.

In some implementations, the recess has a depth of approximately 100 microns, and a width of approximately 3 microns.

In some implementations, the metallic conductor is gold.

In some implementations, the semiconductor substrate comprises silicon.

In some implementations, creating the surface profile characteristics comprises creating shards of silicon grass on the bottom surface of the recess.

In some implementations, creating the surface profile characteristics comprises creating a plurality of protrusions on the bottom surface of the recess.

In some implementations, creating the surface profile characteristics comprises creating a single pointy protrusion on the bottom surface of the recess.

In some implementations, creating the surface profile characteristics comprises creating a bottom surface that bends away from the top opening of the recess.

In some implementations, the bottom surface that bends away from the top opening of the recess includes two or more planar facets joining at an angle.

In some implementations, the bottom surface that bends away from the top opening of the recess includes a smoothly curved surface that arches away from the top opening of the recess.

In some implementations, creating the surface profile characteristics on the bottom surface further includes: applying an insulator coating on the first surface of the semiconductor substrate, the insulator coating covering the side surfaces and the bottom surface of the recess; etching portions of the insulator coating applied on the bottom surface of the recess using a dry etchant, wherein the dry etchant has a greater etch rate for the semiconductor substrate than the insulator coating, and wherein the etching leaves the side surfaces of the recess unexposed when the portions of the insulator coating applied on the bottom surface are completely removed by the dry etchant, and wherein the etching causes the bottom surface of the recess to bend away from the top opening of the recess.

In one aspect, a device includes: a semiconductor substrate, the semiconductor substrate having one or more recesses formed therein, where each recess has one or more side surfaces and a bottom surface, where the bottom surface of each recess includes a respective plurality of protrusions, the plurality of protrusions being shorter than a depth of the recess, where the recess is filled with a plated metallic conductor, and where the plated metallic conductor filled in each recess has respective initial growth sites on the plurality of protrusions residing on the bottom surface of the recess.

In some implementations, each recess has an aspect ratio in a range of 10:1 to 100:1 between a depth of the recess and a width of the bottom surface of the recess.

In some implementations, the device is an x-ray grating, and the plated metallic conductors residing inside the one more recesses and semiconductor material residing between the recesses form a periodic array of linear diffraction elements of the x-ray grating.

In some implementations, the plated metallic conductors residing inside the one or more recesses form a periodic array of linear features, each linear feature has a length of 10 mm to 50 mm, and a width of 2-3 microns in a plane perpendicular to the side surfaces of the recesses, and the periodic array of linear features have a pitch of 4-6 microns.

In some implementations, each recess has a depth of 30-200 microns along the one or more side surfaces, a width of 2-20 microns along the bottom surface.

In some implementations, each recess has a depth of approximately 100 microns, and a width of approximately 3 microns.

In some implementations, the metallic conductor is gold.

In some implementations, the semiconductor substrate comprises silicon.

In some implementations, the plurality of protrusions on the bottom surface of each recess comprises shards of silicon grass formed on the bottom surface of the recess.

In some implementations, the one or more side surfaces of each recess are partially covered by an insulator coating, the insulator coating exposing bottom portions of the side surfaces to the plated metallic conductor inside the recess.

In another aspect, a device includes: a semiconductor substrate having a plurality of recesses formed therein, where each recess has one or more side surfaces, a bottom surface, and a top opening, wherein the plurality of recesses form a periodic array in the semiconductor substrate, where the bottom surface of each recess bends away from the top opening of the recess to form a depression into the semiconductor substrate, and where a depth of the depression measured from a plane in which the side surfaces and the bottom surface intersect is at least one third of a width of the recess.

In some implementations, the bottom surface of each recess is covered by a plated metallic conductor, and the plated metallic conductor fills the recess from initial growth sites on the bottom surface and then up along the side surfaces of the recess.

In some implementations, the periodic array of recesses filled with the plated metallic conductors have dimensions suitable for use as an x-ray diffraction grating.

In some implementations, each recess has a length of 10 mm to 50 mm, a width of 2-3 microns, and a depth of 100-200 microns, and the periodic array has a pitch of 4-6 microns.

In some implementations, the one or more side surfaces of each recess are partially covered by an insulator coating, the insulator coating exposing bottom portions of the side surfaces to the plated metallic conductor inside the recess.

In some implementations, the bottom surface of each recess comprises two or more planar facets joining at an angle.

In some implementations, the bottom surface of each recess is a smoothly curved surface arching away from the top opening of the recess.

In some implementations, each recess has an aspect ratio in a range of 10:1 to 100:1 between a depth of the recess and a width of the bottom surface of the recess.

In some implementations, each recess has a depth of 30-200 microns along the one or more side surfaces, a width of 2-20 microns along the bottom surface.

In another aspect, a device includes: a semiconductor substrate having a plurality of recesses formed therein, where each recess has one or more side surfaces, a bottom surface, and a top opening, where the plurality of recesses form a periodic array in the semiconductor substrate, and where the bottom surface of each recess has one or more protrusions pointing towards the top opening.

In some implementations, the bottom surface of each recess is covered by a plated metallic conductor and the plated metallic conductor fills the recess from initial growth sites on the bottom surface and then up along the side surfaces of the recess.

In some implementations, the periodic array of recesses filled with the plated metallic conductors have dimensions suitable for use as an x-ray diffraction grating.

In some implementations, the plated metallic conductor residing in each recess has respective initial growth sites over respective apexes of the one or more protrusions on the bottom surface of the recess.

In some implementations, the one or more side surfaces of each recess are partially covered by an insulator coating, the insulator coating exposing bottom portions of the side surfaces to the plated metallic conductor inside the recess.

In some implementations, the bottom surface of each recess comprises two or more planar facets joining at an apex at or near a central region of the bottom surface.

In some implementations, each recess has an aspect ratio in a range of 10:1 to 100:1 between a depth of the recess and a width of the bottom surface of the recess.

In some implementations, each recess has a depth of 30-200 microns along the one or more side surfaces, a width of 2-20 microns along the bottom surface.

In some implementations, the protrusions on the bottom surface of each recess are shards of silicon grass formed on the bottom surface of the recess.

In some implementations, each recess has a length of 10 mm to 50 mm, a width of 2-3 microns, and a depth of 100-200 microns, and the periodic array has a pitch of 4-6 microns.

In another aspect, an X-ray diffraction apparatus includes: an X-ray radiation source; an image detector; a first X-ray grating located between the X-ray radiation source and the image detector, the first X-ray grating configured to introduce a given phase difference between X-rays passing through different portions of the first X-ray grating; and a second X-ray grating located between the first X-ray grating and the image detector, the second X-ray grating configured to produce an amplitude interference between the X-rays received from the first X-ray grating, and the second X-ray grating includes: a semiconductor substrate, the semiconductor substrate having one or more recesses formed therein, where each recess has one or more side surfaces and a bottom surface, where the bottom surface of each recess includes a respective plurality of protrusions, where the recess is filled with a plated metallic conductor, and where the plated metallic conductor filled in each recess has respective initial growth sites on the plurality of protrusions residing on the bottom surface of the recess.

In various implementations, the techniques described in this specification provide one or more of the following advantages.

In some implementations, using the techniques described in this specification, a periodic array of linear recesses can be formed in a semiconductor substrate and uniformly and solidly filled with an X-ray absorbing metal (e.g., gold) through electroplating. The resulting structure can have dimensions suitable for use as an X-ray diffraction grating. The X-ray absorption provided by the metal-filled recesses can be very uniform across the entire grating, leading to better precision and contrast in an X-ray imaging device made with the X-ray grating.

The details of one or more implementations of the subject matter described in this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1A is a schematic view of a grating-based X-ray interferometer for phase contrast imaging.

FIG. 1B is a schematic plan view of a grating formed in a semiconductor substrate.

FIG. 1C is a schematic side view of the grating formed in the semiconductor substrate.

FIG. 2A illustrates a conventional technique that would result in the undesirable formation of voids in the plated metal filling of a high-aspect ratio recess in a semiconductor substrate.

FIGS. 2B-2F illustrates another conventional technique that would result in the undesirable formation of voids in the plated metal filling of a high-aspect ratio recess in a semiconductor substrate.

FIGS. 3A-3D illustrate example high depth-to-width aspect ratio recesses that have bottom surface profile characteristics leading to more favorable plating conditions on the bottom surfaces as compared to the side surfaces of the recesses.

FIGS. 4A-4C illustrate the formation of initial growth sites for plated metals inside example high aspect ratio semiconductor recesses having different bottom surface profiles.

FIGS. 5A-5C illustrate an example process for forming an example high depth-to-width aspect ratio recess in a semiconductor substrate, where the recess has a bottom surface that bends away from the top opening of the recess (e.g., the recess shown in FIG. 3A).

FIGS. 6A-6C illustrate another example process for forming an example high depth-to-width aspect ratio recess in a semiconductor substrate, where the recess has a bottom surface that bends away from the top opening of the recess (e.g., the recess shown in FIG. 3A).

FIGS. 7A-7E illustrate another example process for forming an example high depth-to-width aspect ratio recess in a semiconductor substrate, where the recess has a bottom surface that bends away from the top opening of the recess (e.g., the recess shown in FIG. 3B).

FIGS. 8A-8C illustrate another example process for forming an example high depth-to-width aspect ratio recess in a semiconductor substrate, where the recess has a bottom surface that bends toward the top opening of the recess with a single pointy protrusion (e.g., the recess shown in FIG. 3C).

FIGS. 9A-9C illustrate another example process for forming an example high depth-to-width aspect ratio recess in a semiconductor substrate, where the recess has a rough bottom surface that have a small number of pointy protrusions (e.g., one variation of the recess shown in FIG. 3C).

FIGS. 10A-10C illustrate another example process for forming an example high depth-to-width aspect ratio recess in a semiconductor substrate, where the recess has a rough bottom surface that have many pointy protrusions (e.g., the recess shown in FIG. 3D).

FIGS. 11A-11C illustrate an example process for electroplating the example high depth-to-width aspect ratio recesses (e.g., the recesses shown in FIGS. 3A-3D) to fill the recesses from the bottom up.

FIGS. 12A-12F illustrate another example process for forming an example high depth-to-width aspect ratio recess in a semiconductor substrate, where the recess has an exposed bottom surface that bends away from the top opening of the recess and side surfaces entirely protected by an insulator coating.

Many of the layers and features are exaggerated to better show the process steps and results. Like reference numbers and designations in the various drawings indicate like elements.

### DETAILED DESCRIPTION

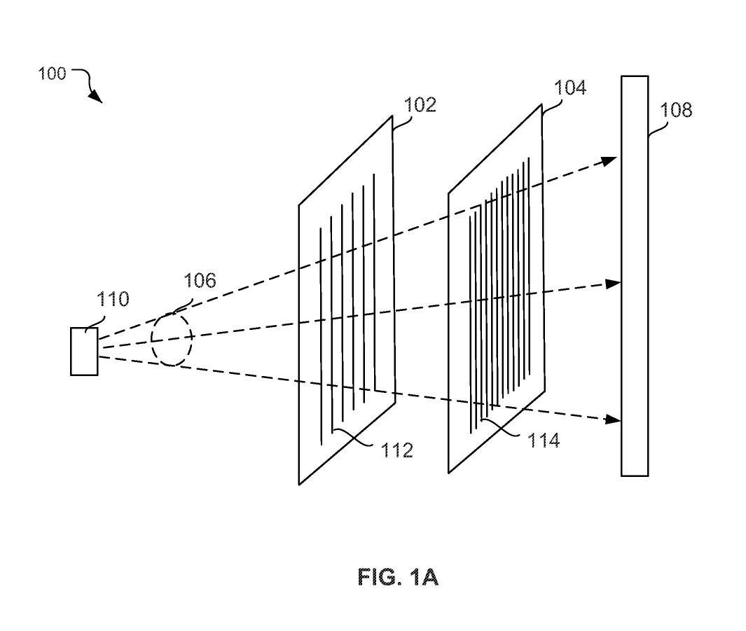

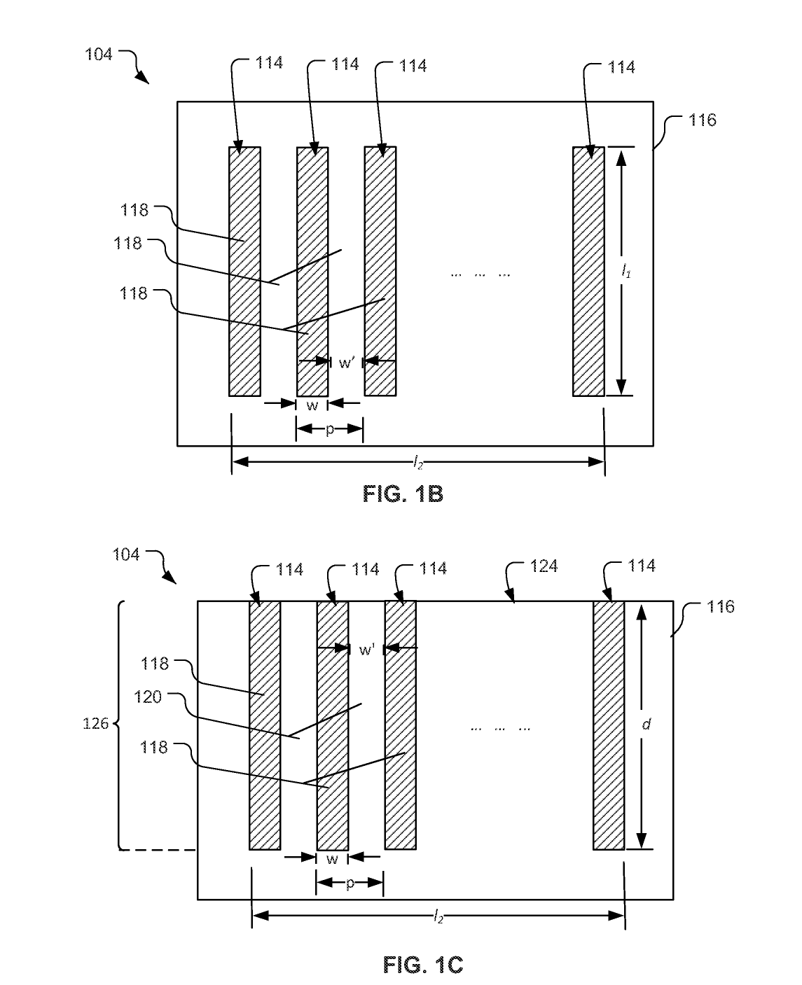

Techniques for fabricating micro-sized, high aspect ratio recesses in a semiconductor substrate can be used in making X-ray gratings in an X-ray phase contrast imaging apparatus. X-ray phase contrast imaging utilizes information on X-ray phase shifts that occur as X-rays pass through a sample, in addition to the information on X-ray absorptions that occur at different parts of the sample. FIG. 1A is a schematic view of a grating-based X-ray interferometer 100 for phase contrast imaging.

As shown in FIG. 1A, the most basic components of the interferometer 100 include two gratings 102 and 104 placed between the object 106 being imaged (e.g., a biological tissue sample) and an image detector 108. The interferometer 100 also includes one or more radiation sources 110 upstream of the object 106. The radiation source 110 emits X-rays onto the object 106. When the X-rays pass through the object 106, the phases and amplitudes of the X-rays are modified by the internal structures of the object 106. In some implementations, when the X-ray sources 110 is not a coherent source, a third grating (not shown) can be placed between the object 106 and the X-ray sources 110 to create a plurality of spatially coherent radiation sources.

The first grating 102 is a weak absorbing, strong phase shifting structure with a pitch of approximately a few tens of microns. The first grating 102 can be made from a planar semiconductor substrate (e.g., a silicon wafer) with parallel linear recesses 112 (e.g., trenches) formed in its front surface. The depth of the linear recesses 112 is chosen to introduce a fixed phase shift (e.g., π) between the X-rays passing through the linear recesses 112 and the X-rays passing through the semiconductor material separating the adjacent linear recesses 112. For example, to generate a phase shift of π in X-rays with a wavelength corresponding to a 40 keV energy level, the depth of the recesses 112 is about 25 microns.

The second grating 104 creates the amplitude interference in the X-rays passing through first grating 102. The second grating 104 includes alternating X-ray transmitting (or weak X-ray absorbing) features and strong X-ray absorbing features. The second grating 104 can be made from a planar semiconductor substrate (e.g., a silicon wafer) with parallel linear recesses 114 (e.g., trenches) formed in its front surface. The linear recesses 114 are filled by a strong X-ray absorbing material, such as gold. The amount of X-ray absorption that can be accomplished through the material (e.g., gold) filling the recesses 114 depends on the height of the material filled inside the recesses 114. The height of the material filled inside the recesses 114 therefore determines the contrast of the images form by the diffracted X-rays passing through the second grating 104.

FIG. 1B is a plan view of an example second grating 104 formed in a semiconductor substrate 116 (e.g., a silicon wafer). The second grating 104 includes a periodic array of linear recesses 114 (e.g., straight walled trenches). The linear recesses 114 are filled with the strong X-ray absorbing material 118 (e.g., Au). The width w of the linear recesses 114 (and hence the width w of the X-ray absorbing material filled inside each linear recess 114) can be approximately one to several microns (e.g., 1.5 micron, 2 microns, or 3 microns). The length l₁ of the linear recesses 114 (and hence the length l₁ of the X-ray absorbing material filled in each linear recess 114) can be much larger than the width w of the linear recesses. For example, the length of the linear recesses 114 can be in the range of tens to hundreds of millimeters (e.g., 30 mm, 60 mm, 100 mm, or 200 mm) depending on the size of the substrate 116 or the required imaging area for the interferometer 100.

The lateral dimension of the grating l₂ can be similar to the length l₁ of the linear recesses 114, such as equal to the length l₁ of the linear recesses 114. The pitch p of the periodic array of linear recesses 114 can be about twice the width w of the linear recesses 114. The semiconductor material 120 between adjacent linear recesses 114 has a width of w′ that is approximately one to a few microns (e.g., 1.5 micron, 2 microns, or 3 microns) as well.

As shown in FIG. 1B, each linear recess 114 has two vertical sidewalls perpendicular to the front surface plane of the semiconductor substrate 116. The distance between the two vertical walls define the width w of the linear recess 114 in the planes parallel to the front surface of the semiconductor substrate 116. When fabricated in a semiconductor wafer, the recesses 114 also has another two opposing vertical sidewalls, and the distance between these two opposing sidewalls define the length l₁ of the linear recesses 114.

FIG. 1C is a schematic side view of the example second grating 104. The side view is taken from a plane perpendicular to the front surface of the semiconductor substrate 116 and the length direction of the linear recesses 114. As shown in FIG. 1C, the linear recesses 114 has sidewalls 122 that are substantially flat and perpendicular to the front surface 124 of the semiconductor substrate 116. The depth d of the linear recesses 114 into the front surface 124 of the semiconductor substrate 116 is also the thickness or height of the X-ray absorbing material 118 (e.g., Au) that is filled inside the recesses 114. The thickness or height d of the X-ray absorbing material 118 determines the imaging contrast produced by the second grating 104. A greater thickness d leads to a higher imaging contrast. Higher energy X-rays require a greater thickness d for the X-ray absorbing material to achieve a given imaging contrast. In some implementations, the depth d of the linear recesses 114 (and hence the thickness d of the X-ray absorbing material 118) carved into the front surface 124 of the semiconductor substrate 116 is in the range of tens to hundreds of microns (e.g., 25 microns-200 microns, 50 microns, 100 microns, or 200 microns).

As shown in FIG. 1C, the recesses 114 does not go through the entire thickness of the semiconductor substrate 116. A layer of semiconductor material remains below the grating layer 126 (i.e., the layer of alternating semiconductor material 120 (e.g., silicon) and X-ray absorbing material 118 (e.g., Au). The thickness of the layer of semiconductor material remaining below the grating layer 126 can depend on the original thickness of the semiconductor wafer 116 in which the grating layer 126 is formed. In some implementations, the wafer 116 may be thinned from one or both sides, as long as the layer of remaining semiconductor material provides sufficient structural support for the grating layer 126 above.

The side view shown in FIG. 1C depicts the linear recesses 114 as high depth-to-width (d:w) aspect ratio recesses formed in the top surface of the semiconductor substrate 116. The height-to-width aspect ratio d:w can be in the range of 10:1 to 200:1 (e.g., 20:1, 50:1, 100:1, 200:1, etc.) in various implementations. From a different perspective, the grating layer 126 can be viewed as alternating layers of X-ray transmitting semiconducting material 120 (e.g., silicon) and X-ray absorbing material 118 (e.g., Au). Each layer has lateral dimensions l₁×d in planes perpendicular to the top surface 124 of the semiconductor substrate 116. The X-ray transmitting layers (i.e., semiconductor layers 120) have a small thickness w′, while the X-ray absorbing layers (i.e., the gold layers 118) have a small thickness w.

Ideally, the X-ray absorbing material (e.g., Au or a gold alloy) fills the entire depth d of each linear recess 114 in the array of linear recesses 114 from the bottom up. In practice, the semiconductor substrate 116 is placed in a plating environment (e.g., a plating bath) containing the metal ions of the X-ray absorbing material, after the recesses 114 have been formed in the semiconductor substrate. During the plating process, the semiconductor substrate 116 can be held at a negative electric potential. The negatively charged semiconductor substrate 116 can serve to provide the negative charges that are needed to reduce the positively charged metal ions in the plating environment into deposits of plated metal on the exposed surface of the semiconductor substrate 116.

Microscopically speaking, during plating, the concentration of the plating metal ions in the plating environment may fluctuate and the availability of negative charges on the exposed surface of the semiconductor substrate 116 may not always uniform across the entire exposed surface of the semiconductor substrate. Therefore, when no step is taken to make the bottom surfaces of the recesses 114 more attractive to the plating metal ions than the exposed side surfaces of the recesses, the initial growth sites of the plating metal has a statistically high likelihood of forming on the exposed side surfaces of the linear recesses 114, especially when the depth-to-width aspect ratio is high.

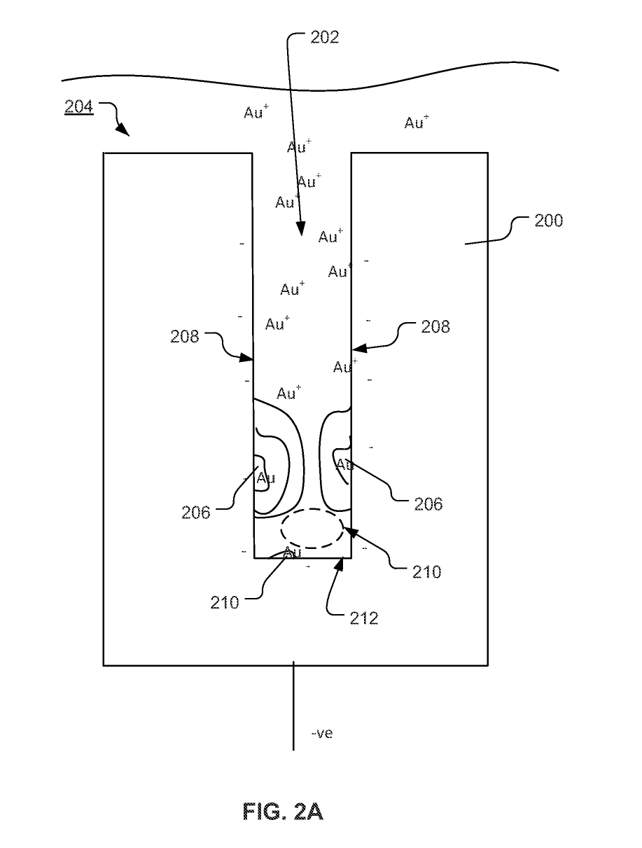

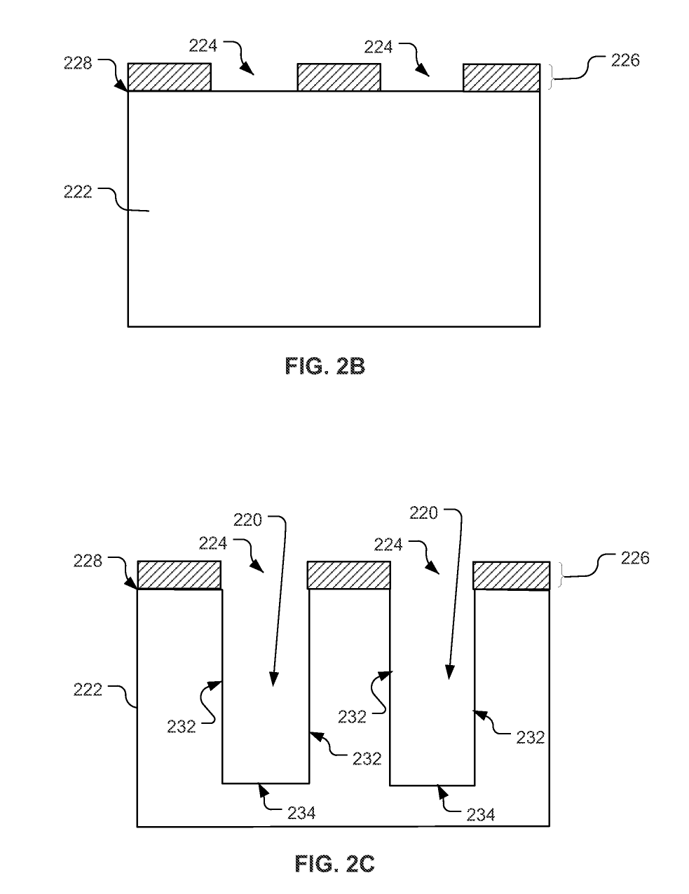

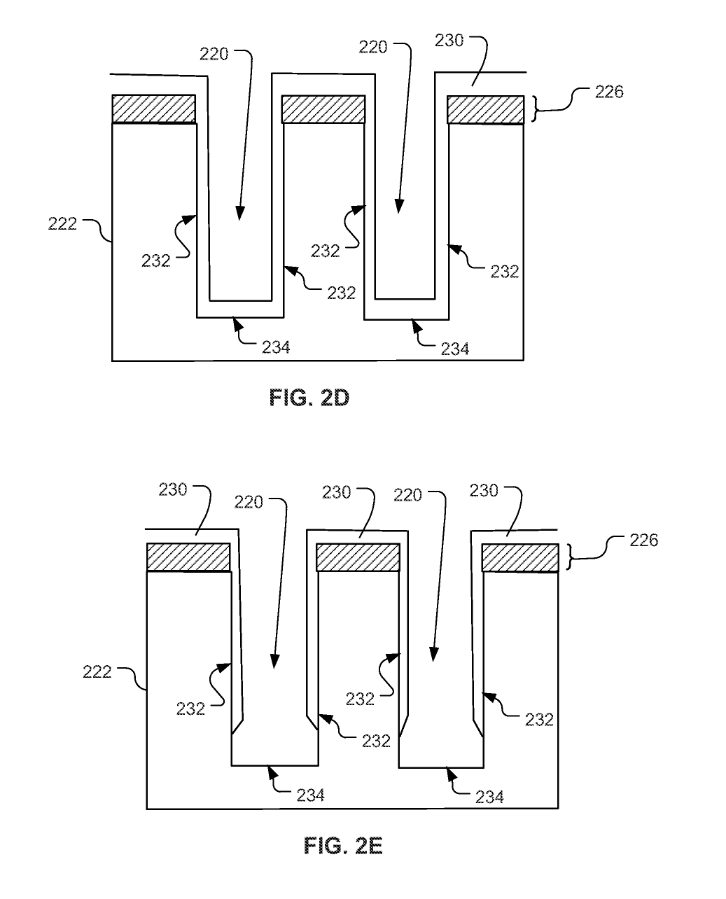

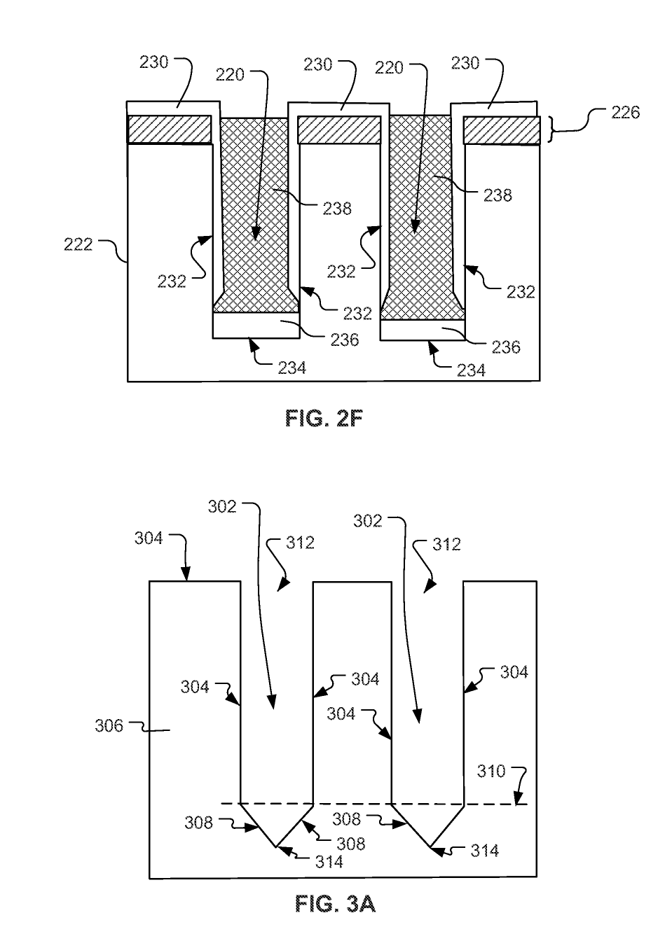

As illustrated in FIG. 2A, when a flat bottomed semiconductor recess 202 in a semiconductor substrate 200 is exposed to a plating environment 204 containing gold ions, there is a high likelihood that the initial deposition sites 206 of the gold ions are formed on the side surfaces 208 of the recess 202. Even if the gold ions may also form initial deposition sites 210 on the bottom surface 212 at around the same time, it is highly likely that the growth of the plating metal from the initial depositions sites 206 on the side surfaces 208 will quickly fill the entire width of the recess 202 before the regions below the growth site 206 are completely filled, and blocking those regions from further contact with the plating environment 204. Therefore, a void 210 (i.e., regions in the recess 202 that is left unfilled) will be created in the recess 202, below the initial growth sites 206 on the side surfaces 208.

As the plated metal continue to grow from the initial growth sites 206 on the side surfaces, more voids may be created along the depth of the recess 202. The problem described above is especially severe when the depth-to-width aspect ratio of the recess 202 is large. An X-ray grating (such as the second grating 104 shown in FIGS. 1A-1C) made with such a plating technique will have non-uniform absorption rate across the different linear recesses, leading to poor contrast and precision of the X-ray grating.

FIGS. 2B-2F illustrates another conventional technique that would result in the undesirable formation of voids in the electroplated metal filling of a high-aspect ratio recess in a semiconductor substrate. First, one or more recesses 220 are created by etching a semiconductor substrate 222 through openings 224 in a mask 226 (e.g., a layer of silicon oxide having linear openings formed therein). As shown in FIG. 2B, a layer of silicon oxide is deposited on the planar front surface 228 of the semiconductor substrate 222. Then openings 224 are formed in the layer of silicon oxide 226, where the openings 224 have the length and width of the linear recesses to be formed in the semiconductor substrate 222.

Then, a Bosch process is used to form the high depth-to-width aspect ratio recesses in the semiconductor substrate 222. The Bosch process includes a series of alternating etching and passivation cycles of short durations, and a Bosch process with thousands of cycles can be used to create micron-sized recesses with depth-to-width aspect ratios up to the hundreds. Each Bosch step includes an etching cycle followed by a passivation cycle. During the etching cycle, an etching gas mixture is first used to etch away a layer of the semiconductor material exposed to the etching gas mixture. Then, during the passivation cycle, a passivation gas mixture is used to form a protective layer on the sidewalls and bottom surface of the recess freshly formed during the previous etching cycle. During the next etching cycle, the etching gas mixture selectively etches through the protective layer formed on the bottom surface of the recess, and etches slightly deeper into the semiconductor substrate, forming a little more sidewalls and a new bottom surface of the recess. As the Bosch steps are repeated, a deep and narrow recess can be formed in the semiconductor substrate (as shown in FIG. 2C). Although not apparent from the drawings, the resulting recess has some small roughness or scalloping on the side walls due to the Bosch cycles.

In this technique, attempts are made to prevent initial deposition sites from forming on the side surfaces of the recess 220. A thin coating of insulator (e.g., an oxide layer 230) is applied (e.g., through Plasma-enhanced chemical vapor deposition (PECVD) or thermal oxidation) over the entire exposed front surface of the semiconductor substrate 222, including the sidewalls 232 and the bottom surfaces 234 of the recesses 220, as shown in FIG. 2D. In some implementations, the layer of insulator 230 can be thicker over the top surface of the semiconductor substrate in areas surrounding the recesses 220.

After the layer of insulator 230 is formed, the bottom surfaces 234 of the recesses 220 are re-exposed by dry etching, so that the re-exposed bottom surfaces 234 can be plated first when exposed to a plating environment. Unfortunately, in the conventional technique, the etchant (e.g., CF₄, CHF₃) used to re-expose the bottom surface has a greater etch rate for the insulator coating (e.g., SiO₂) than for the underlying semiconductor material (e.g., Si). Therefore, as shown in FIG. 2E, when the bottom surfaces 234 are re-exposed through dry etching, portions of the side surfaces 232 near each bottom surface 234 are also re-exposed. In addition, the re-exposed bottom surface remain substantially flat due to the slow etch rate the etchant has with respect to the material of the semiconductor substrate. In addition, some debris resulted from the dry etching can be left on the side surfaces 232 near the bottom surface 234 as well.

Since the process for forming high-aspect ratio recesses (e.g., the Bosch process used in this example) typically produce recesses with smooth and relatively flat bottom surfaces, when the bottom surfaces 234 are re-exposed through dry etching, the bottom surfaces 234 often provide a more inferior deposition condition for the plating metal ions, as compared to the exposed side surfaces 232, especially to portions of the side surfaces 232 near the debris and the edges of the remaining insulator layer 230.

As shown in FIG. 2F, when plating is carried out by exposing the semiconductor substrate 222 shown in FIG. 2E to a plating environment, voids 236 can be formed in the bottom portions of the recesses 220 below the plated metal 238 due to blockage by the plated metal formed first on the side surfaces 232 near the bottom surface 234.

As described in this specification, steps are taken to form high depth-to-width aspect ratio recesses such that the bottom surfaces of the recesses take on surface profile characteristics that make the bottom surfaces more attractive to the plating metal ions in the plating environment, as compared to the exposed side surfaces of the recesses, especially as compared to the portions of the exposed side surfaces in the vicinity of the bottom surfaces.

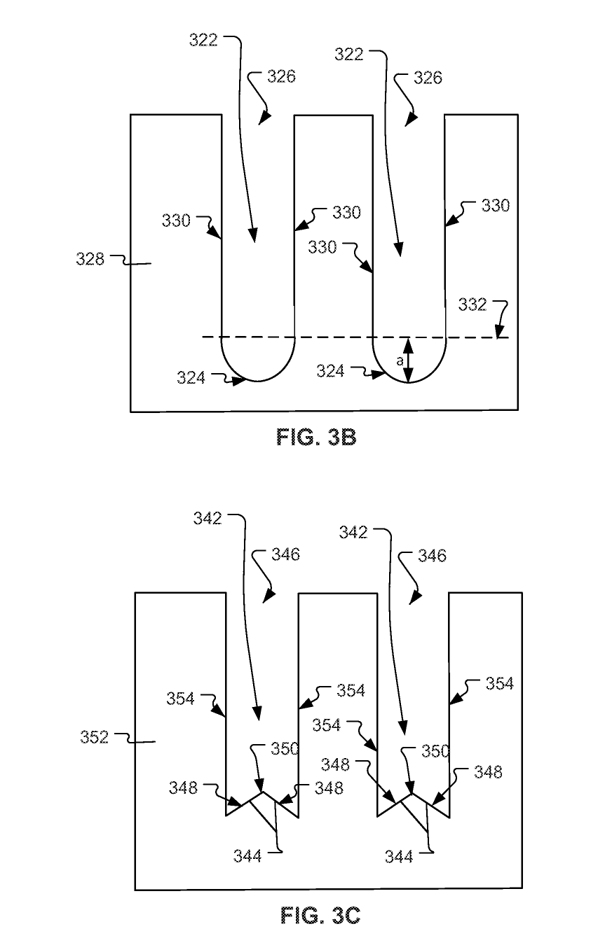

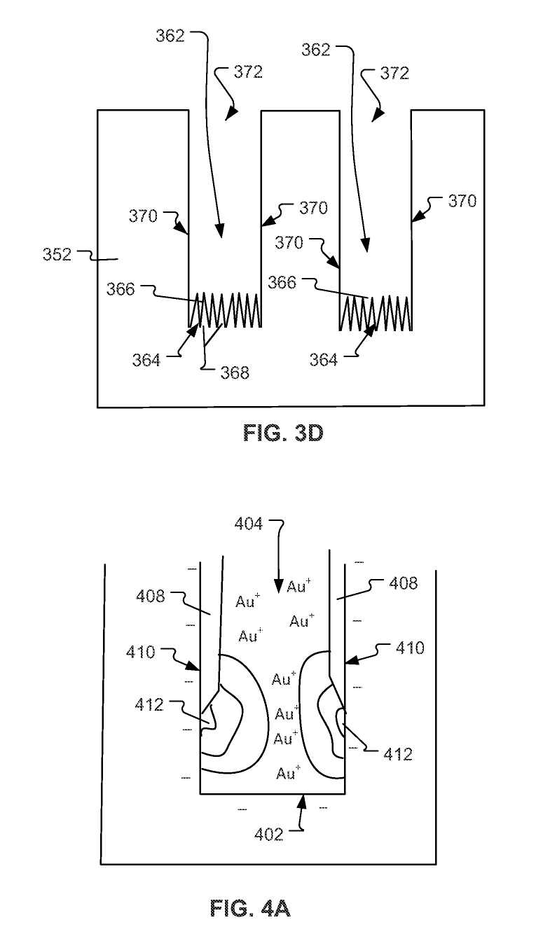

FIGS. 3A-3D illustrate example high depth-to-width aspect ratio recesses that have bottom surface profile characteristics leading to more favorable plating conditions on the bottom surfaces as compared to the side surface(s) of the recesses.

In FIGS. 3A-3B, the bottom surfaces of the recesses bend away from the top openings of the recesses and further into the semiconductor substrate, as compared to a recess having the same depth but a substantially flat bottom surface (e.g., as compared to a recess with a bottom surface made with a conventional Bosch process). Even though in the Bosch process described with respect to FIGS. 2B-2F, the resulting bottom surfaces of the high-aspect recesses may have a slight downward curvature, the amount of deviation from a flat bottom surface is very small and does not make sufficient difference in creating a more favorable plating condition as compared to the sidewalls of recesses.

In contrast, in FIG. 3A, the recesses 302 have vertical sidewalls 304 that are perpendicular to the planar portions of the top surface 304 of the semiconductor substrate 306. In some implementations, the recesses 302 can be a linear recess such as those used in an X-ray grating (e.g., the second grating 104 in FIGS. 1A-1C). In such implementations, the bottom surface of each linear recess 302 includes two planar facets 308. The two planar facets 308 slant away from the plane 310 parallel to the top opening 312 of the recess 302. The two planar facets 308 intersect along a straight line (shown as apexes 314) at or near the center line of the bottom surface. The distance between the apexes 314 and the plane 310 can be at least one third the width w of the recesses 302 (e.g., more than one half of the width w).

In some implementations, the recesses 302 can have a square or rectangular top opening 312, suitable for other types of applications that require micro-sized high depth-to-width aspect ratio recesses. In such implementations, the bottom surface of each recess 302 can have multiple (e.g., four) planar facets that interest at a point at or near the center of the bottom surface.

By creating a high aspect ratio recess having a bottom surface that bends away from the plane parallel to the top opening of the recess, the area of the bottom surface can be enlarged significantly as compared to a recess having the same dimensions but a smooth and substantially flat bottom surface. Since charges tend to flow better near the surface of a semiconductor rather than inside the semiconductor, by increasing the surface area of the bottom surface, the chances for metal ion deposition on the bottom surface can be increased.

The plating metal ions present in a plating environment has a given concentration, without being limited by any particular theories, in the narrow region near the bottom surface of a high-aspect ratio recess, if the side surfaces near the bottom surface are also exposed to the plating environment, the free negative charges in the side surfaces and the bottom surface would compete for the chances to capture the plating metal ions present in that narrow region. When the amount of free negative charges present on the bottom surface is significantly greater than the free negative charges present on the side surfaces near the bottom surface, it is more likely that more of the initial growth sites of the plated metal will be established on the bottom surface first. After these initial growth sites are established on the bottom surface first, the plating can continue as usual and fill the entire length of the recess starting from the bottom surface and then up along the side surfaces. Fewer and smaller voids (if any) would be resulted in the high aspect ratio recess having such a bent bottom surface.

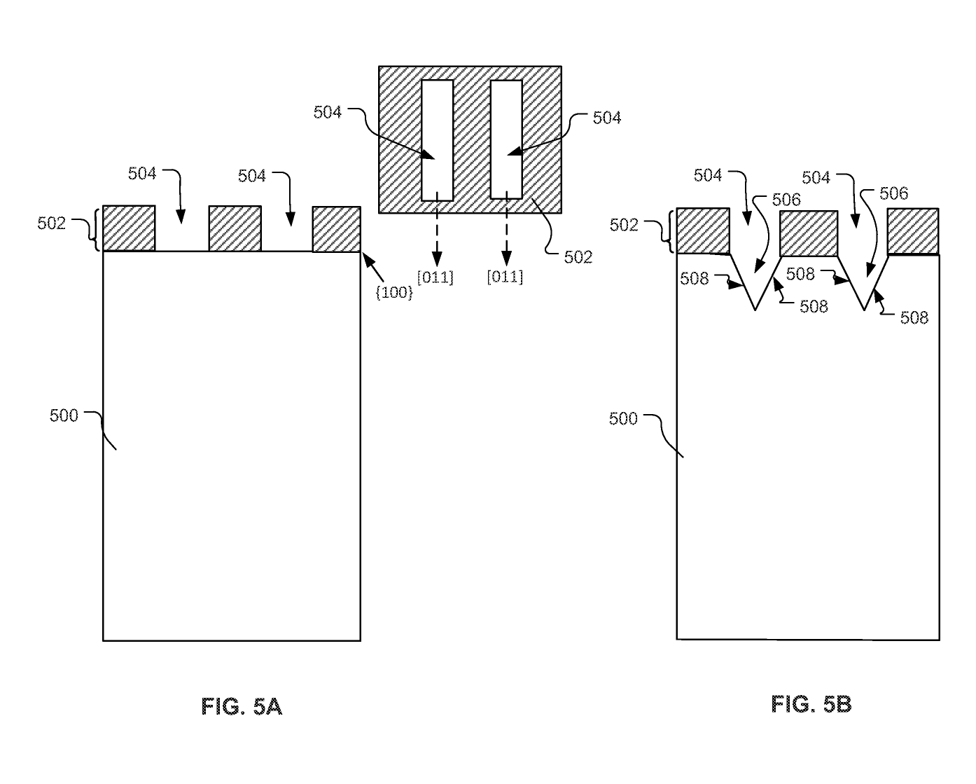

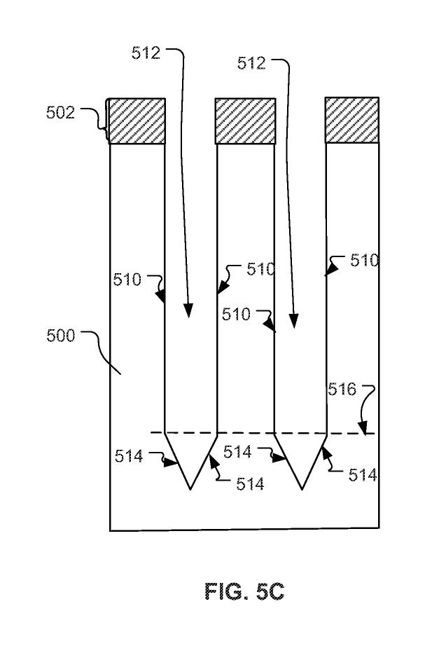

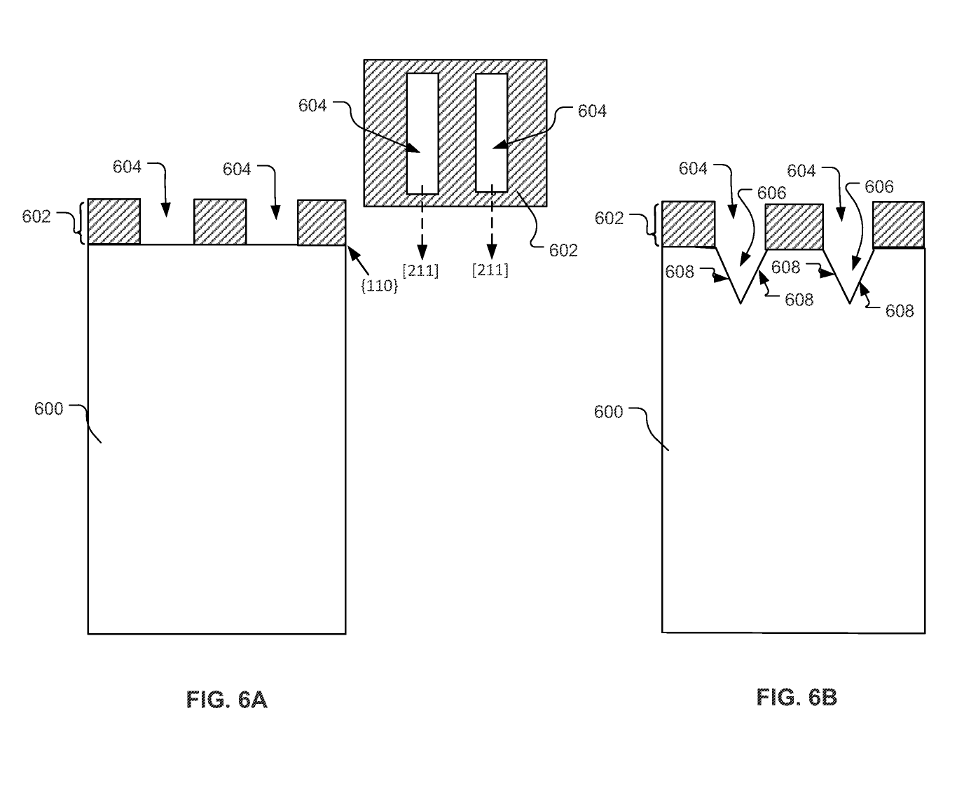

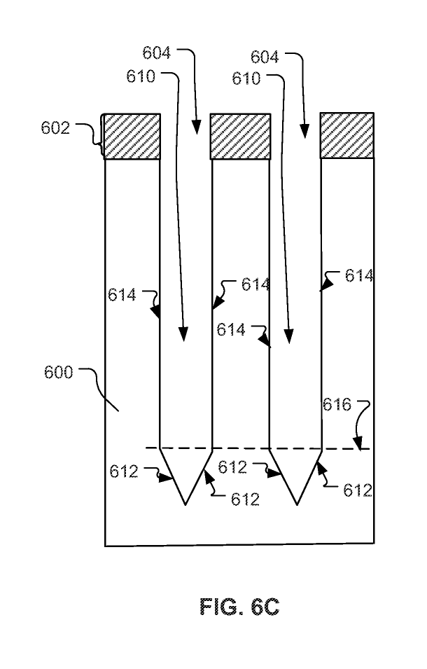

The amount of bending that the bottom surface exhibits can depend on the orientations of crystal planes in the semiconductor substrate. For example, the angle between each planar facet (e.g., the facet 308) of the bottom surface and the plane 310 in which the facet intersects with a side surface 304 (i.e., a plane parallel to the top opening of the recess) can be about 54 degrees, when the facet is along the {111} crystal plane of a silicon substrate created by KOH etching. In some implementations, the etching formula can be customized to create a different amount of bending in the bottom surface. Some example processes for creating the bottom surface profile shown in FIG. 3A are described in more detail with respect to FIGS. 5A-5C and FIGS. 6A-6C.

In addition to the angular bending (as shown in FIG. 3A) in the bottom surface of the recess, the bending in the bottom surface can also be curved. As shown in FIG. 3B, the bottom surface 324 of each recess 322 curves away from the top opening 326 and further into the semiconductor substrate 328. The average radius of curvature of the bottom surface is small enough such that the center of the bottom surface is at least a distance a from the plane 332 in which the bottom surface 324 intersects with the side surfaces 330, where the distance a is a value greater than ⅓ the width w of the recess 322. In some implementations, the distance a can be half the width w of the recess 322, or between w/2 and w/3.

Like the angular bottom surface shown in FIG. 3A, the curved surface profile of the bottom surface 324 shown in FIG. 3B also have the advantage of increased surface area, and hence the increased number of free surface changes in contact with a given volume of plating environment within the recess. In contrast to a flat bottom surface in a high aspect ratio recess, the bottom surface 324 of the recess 322 shown in FIG. 3B provide a more attractive deposition area for the plating metal ions, as compared to the sidewalls 330 of the recess 322 near the bottom surface 324.

When the recess 322 has been coated with an insulator layer that leaves only the bottom surface 334 and the lower portions of the side surfaces 330 exposed to the plating environment (e.g, similar to the configuration shown in FIG. 2E), initial growth sites will be formed on the bottom surface 324 first. Once the initial growth sites are established on the bottom surface 324, the recess 322 can be filled uniformly from the bottom up. Fewer and/or smaller voids (if any) will be resulted in the plated metal formed inside the recess 322, as compared to those found in the plated metal inside a flat-bottomed recess of similar dimensions.

FIG. 3C illustrate another example bottom surface profile that can provide a more favorable plating condition, as compared to a flat bottom surface, and as compared to a smooth side surface of a high aspect ratio recess. As shown in FIG. 3C, the bottom surface 344 of the recess 342 bends toward the top opening 346 of the recess 342. Firstly, the surface area of the bottom surface 344 is greater than the surface area of a flat bottom surface in a recess of the same dimensions. In addition, the bottom surface 344 includes two planar facets 348 that intersect at an angle, and form a pointy apex 350 at or near the center of the bottom surface 344. Since free charges tend to gather near a protrusion on a surface, the surface of the semiconductor substrate 352 near the apex 350 can have a higher concentration of free charges than the side surfaces 354 near the bottom surface 344 when the semiconductor substrate is held at a negative voltage during plating. Therefore, the protruding feature on the bottom surface 344 provides a more attractive deposition area for the plating metal ions than areas of the side surfaces 354 near the bottom surface 344.

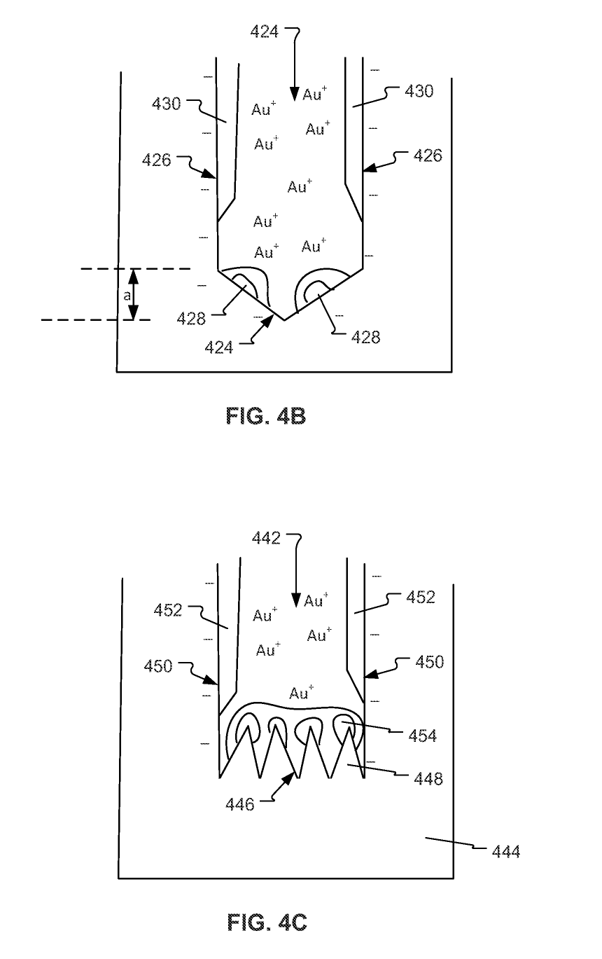

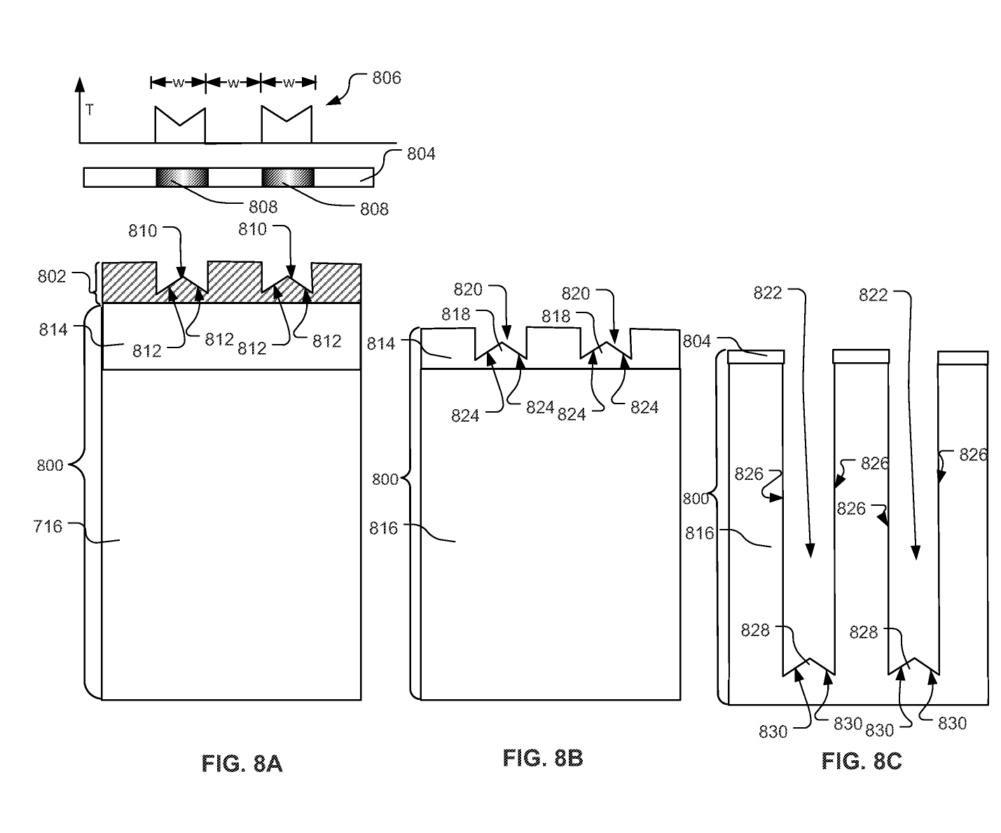

Once the initial growth sites of plated metal are formed over the apex 350 of the bottom surface 344, the plating can continue from the initial growth sites, and fill the recess 342 uniformly from the bottom up. FIGS. 8A-8C illustrate an example process for forming an example high depth-to-width aspect ratio recess in a semiconductor substrate (e.g., the recess shown in FIG. 4C), where the recess has a bottom surface that bends toward the top opening of the recess with a single pointy protrusion.

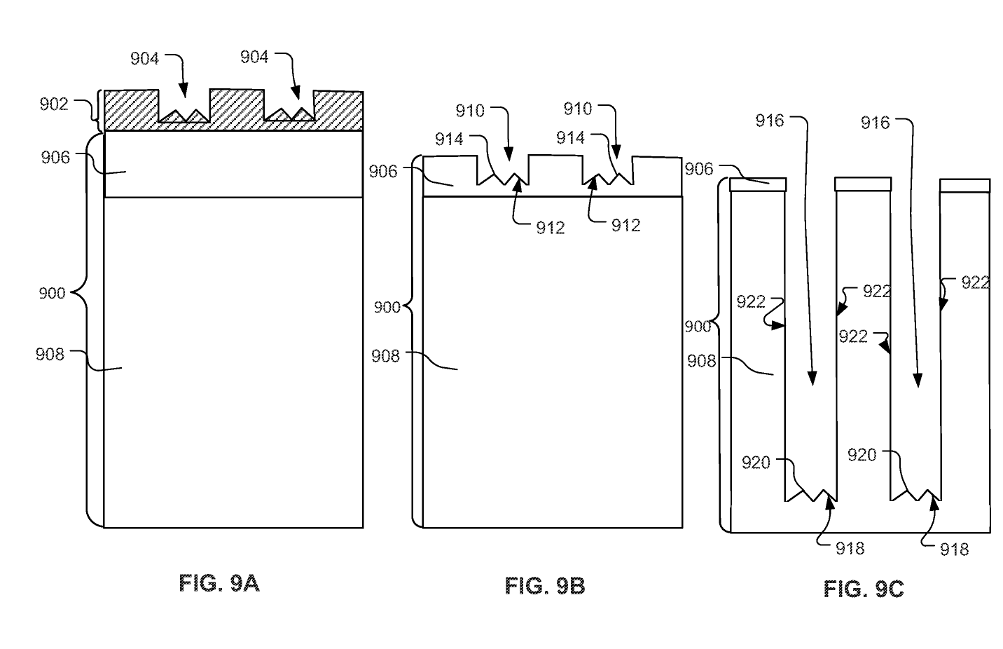

Although one protruding feature is shown on the bottom surface of the recess 342 in FIG. 3C, in some implementations, two or more protruding surface features can be formed on the bottom surface of a recess, such that initial growth sites of the plating metal can be formed on the apexes of the protruding features. FIGS. 9A-9C illustrate an example process for forming an example high aspect ratio recess in a semiconductor substrate that has a small number of pointy protrusions (e.g., a variant of the recess shown in FIG. 4C).

FIG. 3D shows an example high-aspect ratio recess 362 with a bottom surface profile having many pointy protrusions 368. The pointy protrusions 368 form a “grassy” surface texture on the bottom surface 364 of the recess 362. The tips 366 (or apexes) of the pointy protrusions 368 are strongly attractive to the plating metal ions, as compared to the smooth side surfaces 370 near the bottom surface 364. Therefore, when the surfaces of the recess 362 are exposed to a plating environment, initial growth sites of the plated metal will be formed on the tips of the pointy protrusions 368, rather than on the portions of the side surfaces 370 of the recess 362 near the bottom surface 364.

Once the initial growth sites form on the tips 366 of the pointy protrusions 368, as plating continues, the recess 362 will be filled uniformly and solidly by the plated metal, starting from the bottom surface, and then up long the side surfaces. In some implementations, the tips 366 of the pointy protrusions 368 can be roughly positioned on the same level plane parallel to the top opening 372 of the recess 362. In such implementations, when the initial growth sites are formed on the tips 366 of the pointy protrusions 368, the plated metal can have a substantially level bottom surface. Small voids may be formed in the crevices between the pointy protrusions, but these voids are tiny and would not cause much scattering or deterioration of the performance in a grating formed using the recesses 362.

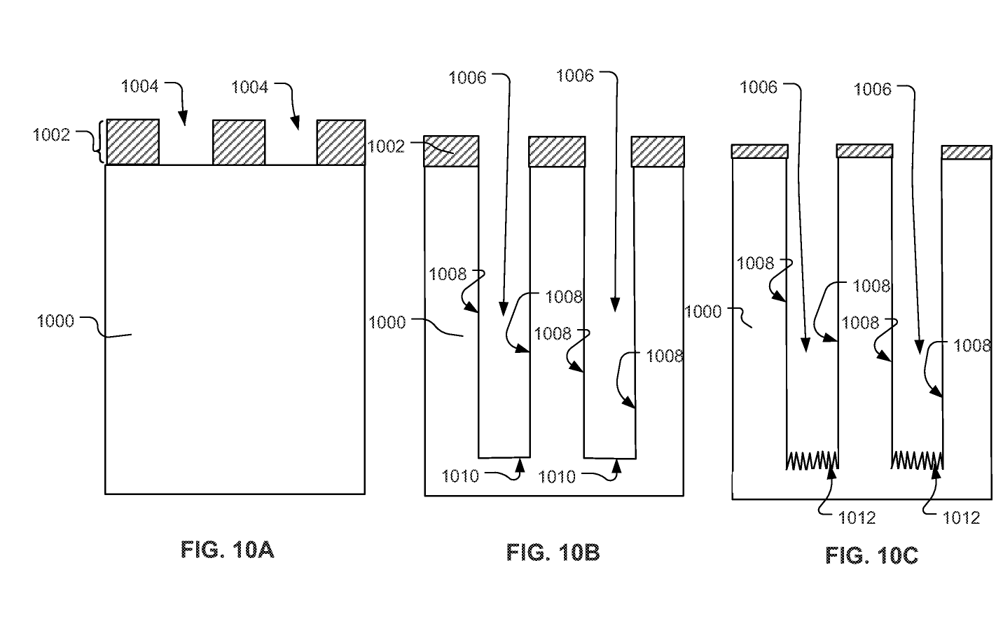

In various implementations, depending on the processing method used to produce the grassy surface texture on the bottom surface of the recess, the pointy protrusions have a different appearance. For example, in some implementations, the pointy protrusions may have a grassy look, and have some degrees of randomness to their locations and dimensions. FIGS. 10A-10C each illustrates an example process for forming an example high depth-to-width aspect ratio recess in a semiconductor substrate, where the recess has a rough bottom surface that have multiple pointy protrusions (as shown in FIG. 3D).

Without being limited by any particular theories, FIGS. 4A-4C illustrate the formation of initial growth sites for electroplated metals inside example high depth-to-width aspect ratio recesses.

FIG. 4A shows an example recess 402 having a smooth and substantially flat bottom surface 404. When the semiconductor substrate 406 containing the recess 402 is held at a negative potential, the free surface charges are more concentrated near the debris and the edge of the insulator coating 408 on the sidewalls 410 of the recess 404 than on the bottom surface 402. The higher concentration of free surface charges on the sidewalls provide a stronger attraction to the metal ions in the volume of plating solution present in the bottom portion of the recess 402. Therefore, more of the initial growth sites 412 of the plated metal are formed on the side surfaces 410 near the bottom surface 402 as opposed to on the bottom surface 402. When the plated metal continues to accumulate over the initial growth sites 412, a void would be formed in regions of the recess 402 below the initial growth sites 412 on the side surfaces.

FIG. 4B shows a high depth-to-width aspect ratio recess 422 having a bottom surface 424 that bends away from the top opening of the recess 422 by a substantial distance. The side surfaces 426 of the recess are covered by an insulator coating 430, except for the lower portions of the side surfaces 426 near the bottom surface 424. The amount of bending in the bottom surface produces a bottom surface area that is significantly larger than the exposed portions of the side surfaces 426 near the bottom surface 424. The larger surface area of the bottom surface 424 means that a greater number of free surface charges are in contact with the small volume of plating solution present in the bottom portion of the recess 422 than the exposed side surfaces 426 near the bottom surface 424. Thus, the initial growth sites 428 of the plated metal are more likely to form on the bottom surface 424, as opposed to the exposed side surfaces 426 near the bottom surface 424. When the plated metal continues to accumulate over the initial growth sites 428, the recess 422 will be filled from the bottom up from the initial growth sites 428 on the bottom surface 424. Although a bottom surface having planar facets are shown in FIG. 4B for illustrative purposes, the same principle described above can apply to a recess having a curved bottom surface that bends away from the top opening of the recess.

FIG. 4C shows a high aspect ratio recess 442 in a semiconductor substrate 444, where the bottom surface 446 of the recess 442 includes one or more pointy protrusions 448 (e.g., silicon grass type surface textures). The side surfaces 450 of the recess 442 are covered by an insulator coating 452, except in the lower portions of the side surfaces 450 near the bottom surface 446. When the semiconductor substrate 444 is held at a negative voltage during plating, free surface charges are highly concentrated on the apexes of the pointy protrusions 448. Thus, the initial growth sites of the plated metal are more likely to form on the bottom surface 454 (at the tips of the pointy protrusions 448), as opposed to the exposed side surfaces 450 near the bottom surface 446. When the plated metal continues to accumulate over the initial growth sites 454, the recess 442 will be filled from the bottom up, starting from the initial growth sites 454 on the bottom surface 446, and then up the length of the recess along the side surfaces 450.

FIGS. 5A-5C illustrate an example process for forming an example high depth-to-width aspect ratio recess in a semiconductor substrate, where the recess has a bottom surface that bends away from the top opening of the recess (e.g., the recess 302 shown in FIG. 3A).

In the example process shown in FIGS. 5A-5C, a semiconductor substrate 500 (e.g., a silicon wafer) having a {100} crystal plane in its planar top surface is used. First, a mask layer 502 is formed on the planar top surface of the semiconductor substrate 500. The mask layer 502 can be a layer (e.g., photoresist, SiO₂, Si₃N₄) patterned with one or more openings 504. Each opening 504 in the mask layer 502 has the same shape and dimensions as the openings of the recesses to be formed in the top surface of the semiconductor substrate 500.

For example, to make the linear recesses for use in an X-ray grating (e.g., the second grating 104 shown in FIG. 1A-1C), one or more linear slots 504 are formed in the mask layer. In this example process, the linear slots 504 formed in the mask layer are oriented such that the length of the linear slots 504 are aligned with the <011> direction of the semiconductor substrate 500, as shown in the plan view (upper right of FIG. 5A) of the top surface of the semiconductor substrate 500, after the mask layer 502 has been patterned.

After the linear slots 504 are formed in the mask layer deposited on the top surface of the semiconductor substrate 500, the top surface of the semiconductor substrate 500 is unisotropically etched using a KOH or Tetramethylammonium hydroxide (TMAH) etching solution. As shown in FIG. 5B, the unisotropic etching selectively etches away the semiconductor material from the exposed top surface of the semiconductor substrate 500 along the {111} crystal planes of the semiconductor substrate. As a result of the etching, a cavity 506 having two opposing planar facets 508 are formed in the exposed top surface of the semiconductor substrate 500. The two opposing planar facets 508 eventually intersect along a straight line at the center of the cavity 506 formed in surface of the semiconductor substrate 500 (as shown in FIG. 5B). The etching can be stopped when the surface profile of the cavity 506 formed by the unisotropic etching has the desired surface profile characteristics needed for the high aspect ratio recess to be formed in the semiconductor substrate 500.

As shown in FIG. 5C, after the unisotropic wet etching to form the cavity 506 is completed, the front surface of the semiconductor substrate 500 can be exposed to dry etching (e.g., in a deep reactive ion etching (DRIE) process) to form the vertical sidewalls 510 of the high aspect ratio recess 512. The dry etching can be stopped when the desired depth of the recess 512 are reached. Since the dry etching can carry out at a substantially uniform rate in the direction perpendicular to the plane of the top opening of the recess 512, the surface profile that the cavity 506 had when the dry etching was first started can be transferred to the bottom surface of the recess 512, as semiconductor material is continually removed from the exposed top surface of the semiconductor substrate 500.

Therefore, once the desired depth of the recess 512 is reached, and the vertical sidewalls 510 of the recess 512 are completely formed by the dry etching process, the bottom surface of the recess 512 includes two planar facets 514 that intersect at a straight line at the center of the bottom surface. The intersection of the two planar facets 514 is at a distance below the horizontal plane 516 in which the bottom surface (i.e., the surface including the facets 514) intersect with the vertical sidewalls 510 of the recess 512. Thus, the high depth-to-width aspect ratio recess shown in FIG. 3A is formed in the semiconductor substrate 500. The semiconductor substrate 500 can subsequently be exposed to a plating environment, and filled from the bottom up with a metallic conductor (e.g., gold) by electroplating.

FIGS. 6A-6C illustrate another example process for forming an example high depth-to-width aspect ratio recess in a semiconductor substrate, where the recess has a bottom surface that bends away from the top opening of the recess (e.g., the recess 302 shown in FIG. 3A).

In the example process shown in FIGS. 6A-6C, a semiconductor substrate 600 (e.g., a silicon wafer) having a {110} crystal plane in its planar top surface is used. First, a mask layer 602 is formed on the planar top surface of the semiconductor substrate 600. The mask layer 602 can be a layer (e.g. photoresist, SiO₂, Si₃N₄) patterned with one or more openings 604. Each opening 604 in the mask layer 602 has the same shape and dimensions as the openings of the recesses to be formed in the top surface of the semiconductor substrate 600.

For example, to make the linear recesses for use in an X-ray grating (e.g., the second grating 104 shown in FIG. 1A-1C), one or more linear slots 604 are formed in the mask layer 602. In this example process, the linear slots 604 formed in the mask layer 602 are oriented such that the length of the linear slots 604 are aligned with the <211> direction of the semiconductor substrate 600, as shown in the plan view of the semiconductor substrate in FIG. 6A.

After the linear slots 604 are formed in the mask layer 602 deposited on the top surface of the semiconductor substrate 600, the top surface of the semiconductor substrate 600 is unisotropically etched using an etchant such as a KOH or TMAH etching solution. As shown in FIG. 6B, the unisotropic etching selectively etches away the semiconductor material from the exposed top surface of the semiconductor substrate 600 along the {111} crystal planes of the semiconductor substrate 600. As a result of the etching, a cavity 606 is formed in the semiconductor substrate 600, where the cavity 606 has two opposing planar facets 608 that eventually intersect along a straight line at the center of the cavity 606.

When the unisotropic etching is continued after the two planar facets 608 of the cavity 606 are joined at the straight line in the center of the cavity 606, the vertical sidewalls 614 of the recess 610 are formed, as shown in FIG. 6C. The vertical sidewalls 614 of the recesses 610 are also along the {111} crystal planes of the semiconductor substrate 600.

Once the desired depth of the recesses has been reached through the continued unisotropic etching using KOH or TMAH, the unisotropic etching process can be stopped. At the end of the etching process, the surface profile of the cavity 606 has been transferred to the bottom surface of the recess 610. The bottom surface of the recess 610 formed in the semiconductor substrate includes two planar facets 612 that intersect at a straight line that is in the center of the bottom surface of the recess 610. The straight line is at a distance below the horizontal plane 616 in which the bottom surface of the recess 610 intersects with the vertical sidewalls 614 of the recess 610. Thus, the high depth-to-width aspect ratio recess shown in FIG. 3A is formed in the semiconductor substrate 600. The semiconductor substrate 600 can subsequently be exposed to a plating environment, and filled from the bottom up with a metallic conductor by electroplating.

Although the two example processes described with respect to FIGS. 5A-5C, and FIGS. 6A-6C produce similar structures, the two example processes are different in at least several respects. For example, the semiconductor substrates used in the two processes have different crystal orientations. In addition, the linear recesses are formed along different crystal directions in the surfaces of the semiconductor substrates. In addition, a two-step etching process (first wet etching, then dry etching) is used to form the entire recess in the process shown in FIGS. 5A-5C, while a single wet etching process is used to form the entire recess in the process shown in FIGS. 6A-6C.

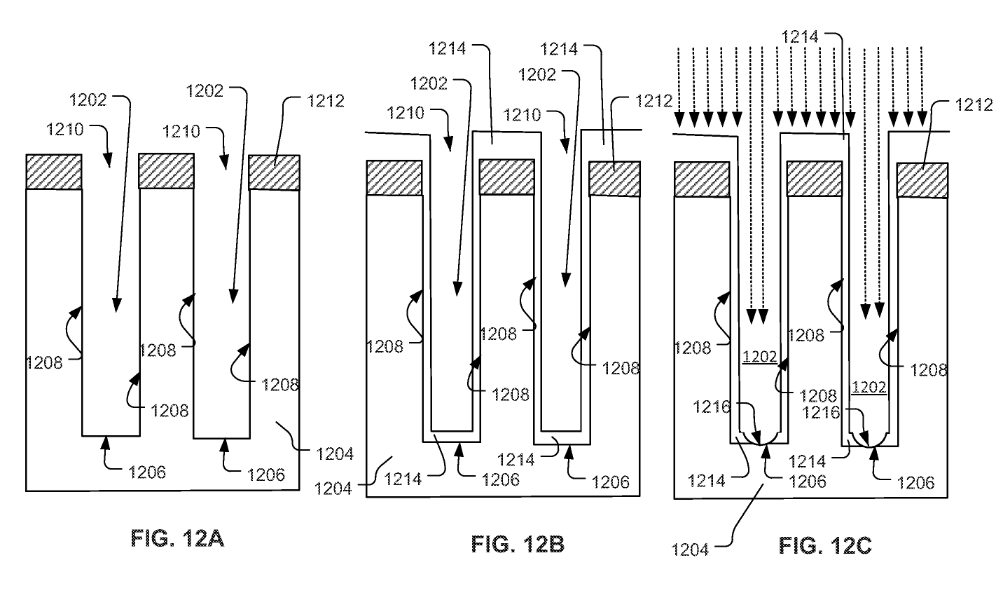

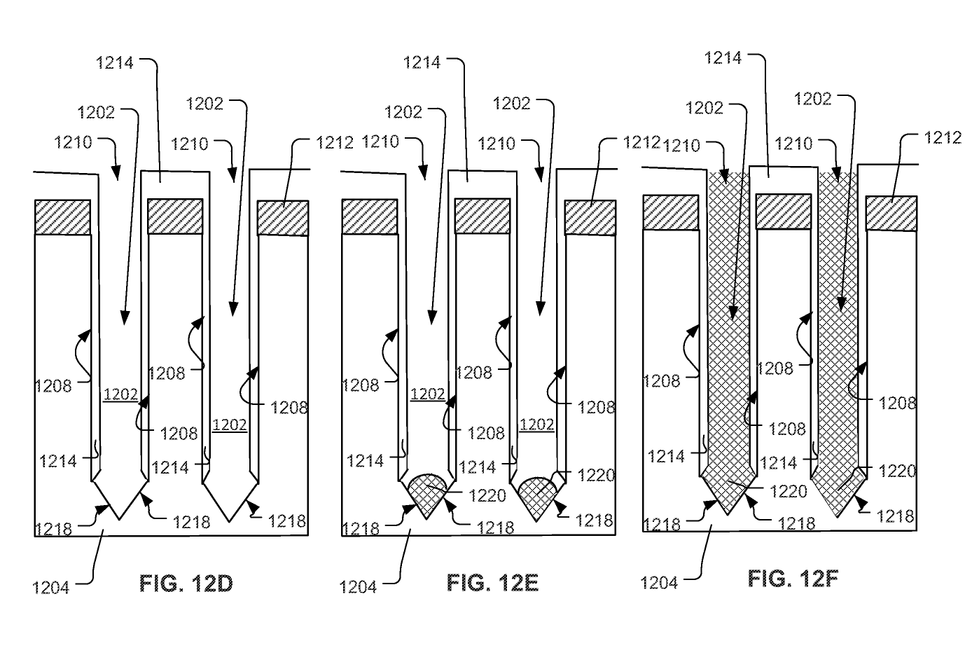

Another example process for forming recesses with a bottom surface that bends away from the top opening of the recess is described later in the specification with respect to FIGS. 12A-12F. The process shown in FIGS. 12A-12F differ from the example processes shown in FIGS. 5A-5C and FIGS. 6A-6C in at least that the bent bottom surfaces of the recesses shown in FIGS. 12A-12F are formed after the inner surfaces of the recesses are formed and coated with an insulator coating.

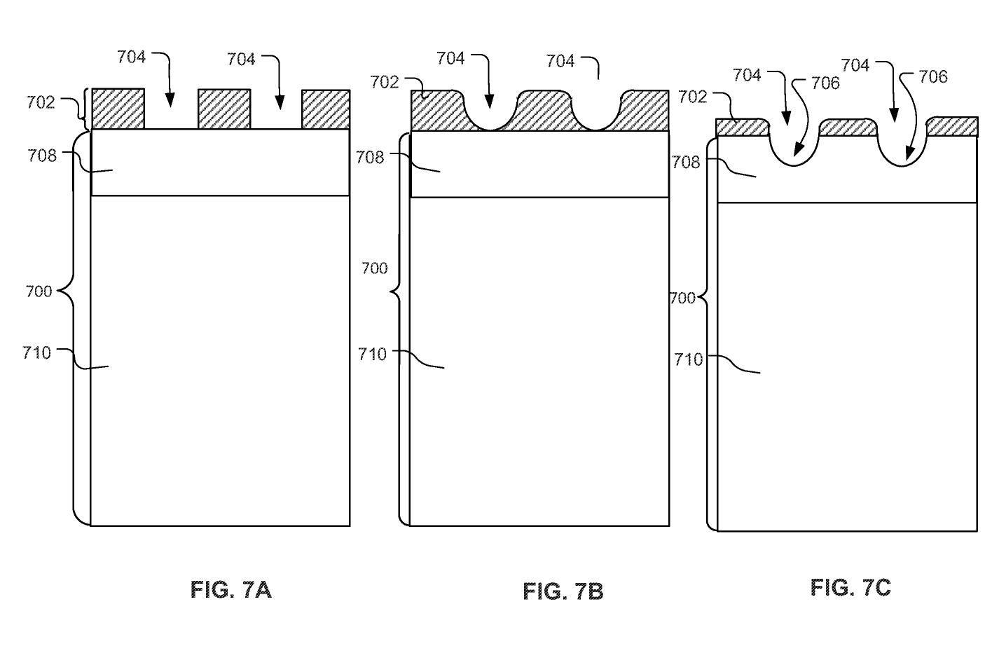

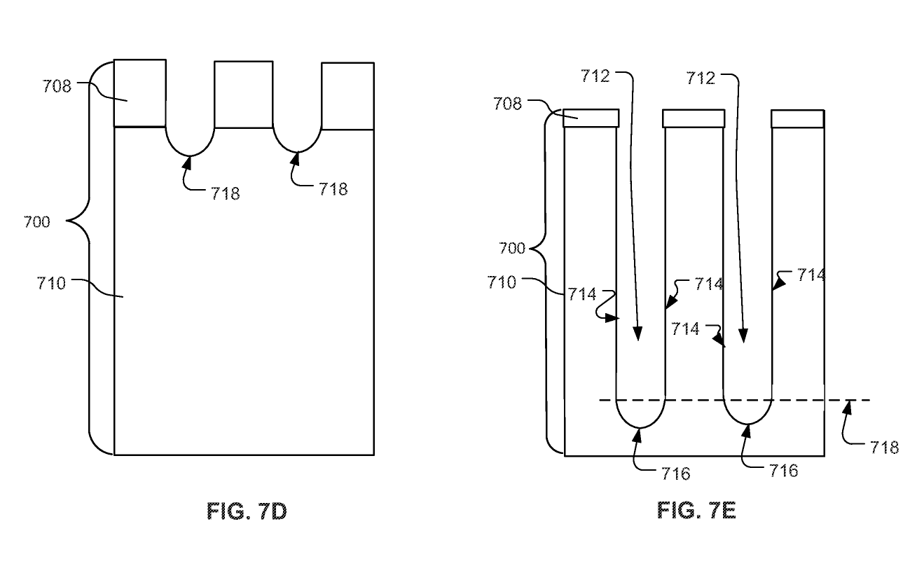

FIG. 7A-7E illustrate another example process for forming an example high depth-to-width aspect ratio recess in a semiconductor substrate, where the recess has a bottom surface that bends away from the top opening of the recess (e.g., the recess shown in FIG. 3B). In this example process, a deep and narrow recess having a bottom surface that curves away from the top opening of the recess is made. Although a high aspect ratio recess formed in a conventional Bosch process may also include a bottom surface that curves slightly away from the top opening of the recess, the bottom surface produced using the process shown in FIGS. 7A-7E would create a much more prominent curve, such that the bottom surface is significantly more attractive to plating metal ions in a plating environment than the flat side surfaces near the bottom surface would.

As shown in FIG. 7A, a layer of photoresist 702 is applied to the planar top surface of a semiconductor substrate 700 (e.g., a silicon wafer, or a silicon-on-oxide wafer). The layer of photoresist 702 is then patterned such that openings 704 are formed in the layer of photoresist 702, and areas below the photoresist within the openings 704 are exposed through the openings 704. The lateral shape and dimensions of the openings 704 formed in the layer of photoresist 702 are roughly equal to the lateral shape and dimensions of the recesses to be formed in the semiconductor substrate 700.

For example, when a linear recess having a length 1, a width w, and a depth d (e.g., the linear recess 104 shown in FIG. 1A) is to be made in the semiconductor substrate 700, the opening 704 in the photoresist layer 702 has lateral dimensions roughly equal to l×w, as well. The thickness of the photoresist layer 702 is at least half of the width w.

Once the openings 704 have been formed in the layer of photoresist 702, the layer of photoresist 702 is annealed at a high temperature (e.g., about 200 degrees Celsius), until the photoresist starts to change its shape. When the openings 704 are initially formed, the sidewalls of the openings 704 are substantially flat and perpendicular to the top surface of the semiconductor substrate 700. Then, the shape of photoresist layer is modified through heating due to half-melting of the photoresist. The counteraction between the weight of the half-melted photoresist and the surface tension created in the half-melted photoresist creates a curved surface profile on the exposed surface of the photoresist layer 702, including the sidewalls of the openings 704 formed in the photoresist layer 702.

Once the curved surface profile is achieved in the layer of photoresist 702, the photoresist layer 702 is cooled such that the photoresist hardens again, but now with the curved surface profile, as shown in FIG. 7B. In some implementations, the exact dimensions of the openings 704 formed in the photoresist layer 702 in FIG. 7A can be adjusted such that the dimensions of the openings 704 formed in the photoresist layer 702 in FIG. 7B have the correct lateral dimensions 1×w.

After the photoresist layer 702 has been cooled and the curved surface profile of the photoresist layer is stabilized, the semiconductor substrate 700 can be etched isotropically, such that the curved surface profile of the photoresist layer 702 is transferred onto the top surface of the semiconductor substrate 700.

In some implementations, the semiconductor substrate 700 can be unitary silicon wafer. After the curved profile of the photoresist layer 702 is transferred to the surface of the cavity 706 formed in the silicon wafer, a Bosch process can be carried out to form the sidewalls of the recess. Since the Bosch process is selective in the vertical direction, as the curved surface profile of the cavity 706 can be transferred onto the bottom surface as the recess is etched deeper and deeper into the semiconductor substrate 700. In implementations where the photoresist layer is used as the mask for the Bosch process, the photoresist layer needs to be relatively thick so that a sufficient thickness remains on the silicon substrate when the cavity 704 is formed in the silicon layer.

In some implementations, the semiconductor substrate 700 used in the process is a silicon-on-insulator substrate, and the layer immediately below the photoresist layer 702 is a layer of silicon oxide 708. The layer of silicon oxide 708 has a thickness of at least a few microns (e.g., 2-4 microns), such that curved profile of the photoresist layer 702 can be completely transferred onto the surface of the oxide layer 708 when the oxide layer 708 is etched using an isotropic etchant through the layer of photoresist 702.

As shown in FIG. 7C, the etching of the silicon oxide layer 708 is carried out until the curved profile of the photoresist layer 702 has been transferred onto the surface of the oxide layer 708. In other words, a cavity 706 having the curved surface profile is formed in the surface of the oxide layer 708. Then, any remaining photoresist is removed to expose the layer of oxide 708. In some implementations, the layer of oxide 708 is optionally polished such that the top surface outside of the cavity 706 is planarized. The layer of oxide 708 can then be used as a mask layer to form deep, narrow recesses 712 in the silicon layer 710 beneath the oxide layer 708 using a Bosch process.

As shown in FIGS. 4D and 4E, as the Bosch process continues with the alternating etching and depositing phases, the vertical sidewalls 714 of the a deep and narrow recess 712 is gradually formed in the silicon layer 710 of the semiconductor substrate 700. The bottom surface 716 of the recess 712 maintains the curvature of the surface 718 of the cavity 720 previously present in the oxide mask layer 708.

Although the bottom surface of the recesses formed using a Bosch process and a regular vertical-walled mask (rather than an oxide mask whose openings have curved sidewalls as shown in FIG. 7C) can be curved slightly, the amount of curving, i.e., the distance between the lowest part of the bottom surface and the plane in which the side surfaces intersect with the bottom surface, is only in the range of a few tenths of a micron or less. In contrast, when the process shown in FIGS. 7A-7E is used, the amount of curving i.e., the distance between the lowest part of the bottom surface 716 and the plane 718 in which the side surfaces 714 intersect with the bottom surface 716, can be as much as half the width w of the recess 712.

In some implementations, for a deep recess with a depth of 100 microns, and a width of 2 microns, the distance between the lowest point of the bottom surface 716 and the plane 718 in which the bottom surface 716 intersect with the vertical side surfaces 714 can be as much as 1 micron.

Without being limited by any particular theory, one advantage of using the silicon oxide layer 708 as the mask layer for the Bosch process is that, unlike a regular photoresist layer, the oxide layer 708 does not have the problem of cracking and disintegrate after a prolonged Bosch process. Therefore, for producing high-aspect ratio recesses with large depths (e.g., depth in the range of 100 microns), the oxide layer is used as the mask for the Bosch process. Even though some of the oxide layer may be attacked and thinned during the Bosch process, it does not have the cracking issue that a layer of photoresist may have. In some implementations, the oxide layer can be removed or planarized after the recesses 712 have been formed.

FIG. 8A-8C illustrate another example process for forming an example high depth-to-width aspect ratio recess in a semiconductor substrate, where the recess has a bottom surface that bends toward the top opening of the recess with a single pointy protrusion (e.g., the recess 342 shown in FIG. 3C).

In this example process, a grayscale mask is used to create a thickness profile with a pointy surface feature at each location under which a recess would be formed in the semiconductor substrate. Then the photoresist layer is used as a mask to form the recesses in the semiconductor substrate.

As shown in FIG. 8A, a layer of photoresist 802 is applied to the planar surface of a semiconductor substrate 800. Then the layer of photoresist 802 is exposed to ultraviolet radiation through a grayscale mask 804. The grayscale mask is specially designed to allow a different amount of ultraviolet light through at different locations on the grayscale mask according to a transmission profile of the grayscale mask. In this particular example, the grayscale mask 804 is designed such that it transmits UV light only in regions that map to the locations of the recesses to be formed in the surface of the semiconductor substrate 800. The transmission profile 806 of the grayscale mask is shown at the top of FIG. 8A.

As shown in the transmission profile 806, to form linear recesses with length/and width w in the surface of a semiconductor substrate 800, the grayscale mask 804 only allows UV light to pass through stripes of areas 808 having length/and width w at locations matching the locations of the recesses to be formed (e.g., with a pitch of 2w). In addition, the amount of light that passes through the stripes 808 is the largest at the edges of the stripes 808 in the width direction, and decreases linearly with increasing distance away from the edges and toward the center of each stripe 808.

When the planar layer of photoresist 802 is exposed to UV light through the grayscale mask 804, and then developed, the photoresist layer 802 becomes patterned not only in the lateral dimensions, but also in the depth dimension. As shown in FIG. 8A, after the photoresist layer 802 is developed, the profile of the photoresist layer 802 shows the inverse of the UV transmission profile 806 of the grayscale mask 804. Specifically, the photoresist layer 802 has planar portions in areas that were not exposed to any UV light through the grayscale mask 804. In areas where UV light were transmitted through the grayscale mask 804 onto the photoresist layer 802 (i.e., in areas of the photoresist layer 802 below the transmitting stripes 808 of the grayscale mask 804), the surface profile of the photoresist layer 802 is the inverse of the transmission profile 806 of the grayscale mask 804. In other words, the patterned photoresist layer 802 now has a surface profile that has a single pointy protrusion 810 pointing away from the planar bottom surface of the photoresist layer 802. In this particular example, the single pointy protrusion 810 has two flat facets 812 that meet at a single straight line along the length/of the dented portion of the photoresist layer 802.

Once the photoresist layer 802 has been patterned in both the lateral dimensions and the depth dimension according to the lateral dimensions and the bottom surface profile of the recesses 822 to be formed in the semiconductor substrate 800, the process for forming the recesses 822 can be carried out through the photoresist layer 802. In some implementations, the recesses 822 can be formed by a dry etching process, such as a plasma etching process. In some implementations, the recess 822 may be formed using a Bosch process.

In some implementations, if deep recesses are to be formed using the Bosch process, the semiconductor substrate 800 can be a silicon on oxide wafer, including an oxide layer 814 and a silicon layer 816. During the etching, the profile of the photoresist mask 802 is transferred to the oxide layer 814 first. Then, the photoresist layer 802 can be removed, and the oxide layer 814 can serve as the mask layer for the subsequent Bosch process that forms the full length of the recesses 822 in the underlying silicon layer 816. As shown in FIG. 8B, before the Bosch process is started, straight-walled cavities 824 have been formed in the oxide layer 814 at locations under which the recesses 822 will be formed in the silicon layer 816 through further etching. A single pointy protrusion 818 is formed on the bottom surface of each cavity 824.

Then, the Bosch process can be carried out, and the surface profile of the oxide layer 814 inside the cavities 824 is transferred to the bottom surfaces of the recesses 822, as the recesses 822 become deeper and deeper with each etching and passivation cycles of the Bosch process. The Bosch process can be stopped when the full depth of the recess 822 has been reached. The resulting recesses 822 have vertical sidewalls 826, and bottom surfaces each including a single pointy protrusion 828. The single pointy protrusion 828 in each recess 822 points toward the top opening of the recess 822. In FIG. 8C, the single pointy protrusion has two planar facets 830 meeting at a straight line. In some implementations, a single pointy protrusion with other surface profiles may be formed using the process shown in FIGS. 8A-8C.

The techniques described above can not only be used to produce a single pointy protrusion on the bottom surface of a recess, but also multiple pointy protrusions on the bottom surface of a recess, as long as a mask having the appropriate UV transmission profile is used. FIGS. 9A-9C illustrate another example process for forming an example high depth-to-width aspect ratio recess in a semiconductor substrate, where the recess has a rough bottom surface that have a small number of pointy protrusions (e.g., a variation of recess 342 shown in FIG. 3C).

As shown in FIG. 9A, a different grayscale mask has been used to pattern the photoresist layer 902 deposited on a semiconductor substrate 900. For example, the grayscale mask can have a transmission profile that creates a thickness profile in the regions 904 in the photoresist layer 902 that match the lateral shapes and locations of the recesses to be formed in the semiconductor substrate 900. The thickness profiles of the patterned photoresist layer 902 can have a small number of pointy protrusions arranged in a periodic array (e.g., a 2×2 array), for example.

As shown in FIG. 9B, when the semiconductor substrate 900 is exposed to etching through the patterned photoresist layer 902, the surface profile of the photoresist layer 902 inside the regions 904 is transferred onto the surfaces 912 of the cavities 910 formed through the etching (e.g., anisotropic wet etching). In other words, the surface 912 of the cavities 910 will have protruding features 914 arranged in a small periodic array. In addition, the cavities 910 have vertical sidewalls that define the lateral shapes and dimensions of the recesses to be formed in the semiconductor substrate 900.

In some implementations, the semiconductor substrate 900 is a silicon-on-oxide wafer, and includes an oxide layer 906 and a silicon layer 908. The layer immediately below the patterned photoresist layer 902 is the oxide layer 906. When the oxide layer 906 is etched through the patterned photoresist 902, the vertical profile of the photoresist layer 902 is transferred onto the surface of the oxide layer 906. Then the photoresist layer 902 is removed, and the patterned oxide layer 906 is used ask the mask for the subsequent etching of the silicon layer 908 underneath.

In some implementations, a Bosch process can be used to form the entire depth of the recesses 916 in the silicon layer 908. Each recess 916 would have vertical sidewalls 922 and a bottom surface 918. The bottom surfaces 918 of the recess 916 would include pointy protrusions 920 that match the protrusions 914 on the bottom surface 912 of the cavities previously present in the oxide layer 906. The bottom surface 918 of the recess 916 has sufficient roughness to provide a more favorable deposition area for the plating metal ions, as compared to the vertical side surfaces 922 of the recess 916. When the recess 916 is exposed to a plating environment, initial growth sites of plated metal will be formed over the pointy protrusions 920 on the bottom surface 918 of the recess.

Although in the above example processes, only a limited number of recesses are shown for illustrative purposes, a person skilled in the art would recognize that arrays of the recesses can be formed using the same techniques and with appropriate mask patterning.

FIG. 10A-10C illustrate another example process for forming an example high depth-to-width aspect ratio recess in a semiconductor substrate, where the recess has a rough bottom surface that have a large number of pointy protrusions (e.g., the recess 362 shown in FIG. 3D).

In this example process, a patterned mask 1002 is formed on a semiconductor substrate 1000, as shown in FIG. 10A. In some implementations, the patterned mask 1002 can be a patterned oxide layer of a silicon-on-oxide wafer, and the semiconductor substrate 1000 can be the silicon layer of the silicon-on-oxide wafer. The patterned oxide mask has straight-walled openings 1004 at locations where the recesses are to be formed in the underlying semiconductor substrate 1000. The openings 1004 have the same lateral dimensions as the recesses to be formed in the semiconductor substrate 1000.

Once the oxide mask 1002 has been prepared, a Bosch process can be carried out through the oxide mask 1002 to make the recesses 1006 in the semiconductor substrate 1000. The Bosch process includes alternating etching and passivation phases. During the etching phase, a specific gas mixture (e.g., a SF₆ gas) is directed toward the surface of the substrate 1000 in the vertical direction for a predetermined period of time (i.e., the etching period). The etching gas mixture attacks the exposed surfaces of the semiconductor substrate, and makes the recess a little deeper at the bottom. Since the etching gas mixture also attacks the semiconductor substrate in the lateral directions as well, the etching phase must be kept relatively short, (e.g., a few seconds) to keep the width of the recess 1006 close to the width of the openings 1004.

When the passivation phase starts, a different gas mixture (e.g., a C₄F₈ gas) is used to encourage formation of a protective layer on the sidewalls and bottom surface of the recess 1006 that have just been exposed by the previous etching phase. After the passivation period, the etching phase is started again, using the etching gas mixture. The etching gas mixture attacks the protective layer formed on the bottom surface, but leaves the protective layer on the side surfaces relatively intact. Once the etching gas mixture penetrates the protective layer on the bottom surface, the etching gas mixture etches further into the semiconductor substrate 1000, and makes the recess 1006 a little deeper before the etching phase ends again. The alternating etching and passivation phases of the Bosch process can be repeated thousands of times to form a high aspect ratio recess of a desired width and depth.

During the above Bosch process to make the recesses 1006 in the semiconductor substrate 1000, the respective gas pressure, temperature, gas mixture composition, and duration of the etching phase and the passivation phase (or collectively the “etching recipe” of the Bosch process) are carefully chosen such that the sidewalls 1008 and the bottom surfaces 1010 of the recesses 1006 are smooth and flat. In this example, the recipe for forming a high-aspect ratio recess can form sidewalls having undulations in the range of a few nanometers.

As shown in FIG. 10B, the entire sidewalls 1008 of the high-aspect ratio recesses 1006 have been formed using a first Bosch recipe, tailored to produce deep, narrow recesses having substantially flat, vertical sidewalls and a substantially level and smooth bottom surface. Then, a second, different Bosch recipe is used to alter the surface texture of the bottom surface 1010 of the recesses 1006. The second recipe can be based on the first recipe, but is modified to encourage deposition of the protective materials, and/or to decrease the etch rate. For example, in the second recipe, the pressure can be increased and/or the temperature can be decreased during the etching phase, as compared to the first recipe. In addition, or alternatively, in the second recipe, the C₄F₈ gas concentration can be increased in the deposition gas mixture to encourage more deposition material during the deposition phase, as compared to the first recipe. In addition, in the second recipe, the passivation duration can be increased, as compared to the first recipe.

As shown in FIG. 10C, the Bosch process using the second recipe may increase the depth of the recesses 1006 slightly, but more importantly, grass like surface features (also called “silicon grass”) will be formed on the bottom surface 1012 of the recesses 1006. The grass-like surface features are pointy shards of semiconductor materials that have the appearance of grass blades. Without being limited by any particular theories, these grass-like surface features can be the result of micro-masks produced by the particles of deposits formed on the bottom surface of the recesses 1006 during the second Bosch etching process. The second etching process can be stopped when the desired bottom surface texture is achieved.

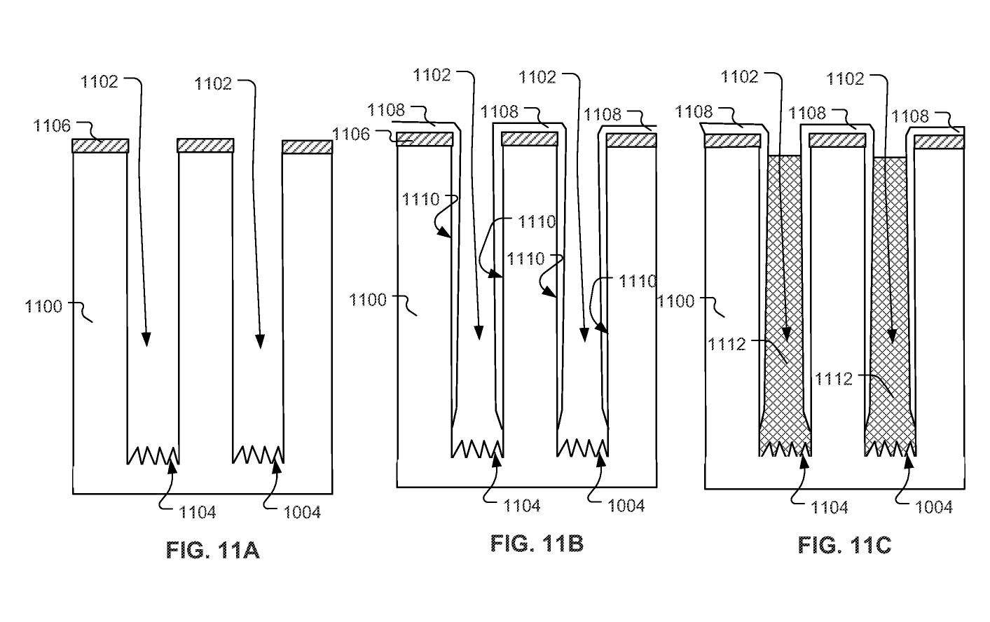

FIGS. 11A-11C illustrate an example process for electroplating the example high depth-to-width aspect ratio recesses (e.g., the recesses shown in FIGS. 3A-3D) to fill the recesses from the bottom up. The process shown in FIGS. 11A-11C can be performed after each of the processes described with respect to FIGS. 5A-10C, for example. In the example shown in FIGS. 11A-11C, the recesses having rough bottom surfaces (e.g., a bottom surface having silicon grass on it) are plated by a metal (e.g., gold). However, the same plating technique can be applied to recesses having other surface profiles described in this specification.

As shown in FIG. 11A, the high-aspect ratio recesses 1102 having specially prepared bottom surface profiles to promote plating have been prepared in a semiconductor substrate 1100. The bottom surface 1104 of each recess 1102 has a plurality of protruding surface features (e.g., silicon grass). In some implementations, a layer of oxide 1106 (e.g., a mask layer used in a Bosch process for forming the recesses 1102) may remain on the top surface of the semiconductor substrate 1100. Then, the top surface of the semiconductor substrate 1100 is coated with a thin layer of insulator 1108, as shown in FIG. 11B. The insulator layer 1108 can be thicker on planar portions of the top surface that surrounds the recesses 1102, and gets thinner as it goes deeper into the recesses 1102. The insulator coating 1108 can be an oxide layer can be applied by PECVD or thermal oxidation.

In some implementations, the insulator coating 1108 does not reach the bottom surfaces 1104 of the recesses 1102 when the recesses 1102 are sufficiently narrow and deep. In some implementations, if the insulator coating 1108 does reach and cover the bottom surfaces 1104 of the recesses 1102 as well as the sidewalls 1110 of the recesses 1102, steps can be taken to remove the coating from the bottom surfaces 1104 of the recesses 1102, e.g., by dry etching. The insulator coating 1108 has a thickness of 100-500 angstroms, for example. The insulator coating 1108 prevents plating from occurring on the side surfaces of the recesses 1102 before the plating occurs on the bottom surfaces 1104 of the recesses 1102.

In the example shown here, although the bottom portion of the side surfaces 1110 may be exposed, and not covered by the insulator coating 1108, initial growth sites of the plating metal are more likely to be formed on the bottom surfaces 1104 of the recesses 1102 due to the special surface profile characteristics that have been created on the bottom surfaces 1104 (e.g., using the techniques described earlier in this specification). FIG. 11C shows that once the semiconductor substrate 1100 is exposed to a plating environment, such as a plating bath containing gold ions, the initial growth sites of plated metal are formed on the bottom surfaces 1104 of the recesses 1102, and the recesses 1102 are filled solidly and uniformly from the bottom up from the initial growth sites by the plated metal 1112. In some implementations, the metal filled inside the recesses 1102 can be used as the X-ray absorbing elements of the X-ray grating 104 shown in FIG. 1A-1C, for example.

In the example process shown in FIGS. 11A-11C, the insulator coating is applied to the recesses after the bottom surfaces of the recesses have been formed to include the surface profile characteristics that promote formation of the initial growth sites for the plated metal. In another example process shown in FIGS. 12A-12F, a flat-bottomed recess is formed first. Then, the inner surfaces of the recess (including the bottom surface and the side surfaces) are coated with an insulator coating. Unlike the conventional process shown in FIGS. 2B-2F, in the example process shown in FIGS. 12A-12F, the bottom surface of the recess is re-exposed using a different dry etching process (e.g., by a different etchant) that preferentially re-expose the bottom surface of the recess without re-exposing the side surfaces of the recess. Thus, when the recess is exposed to the plating environment afterwards, the plating metal can only deposit onto the re-exposed bottom surface of the recess, and start to fill the recess from the bottom up.

As shown in FIG. 12A, one or more high depth-to-width aspect ratio recesses 1202 have been formed in a semiconductor substrate 1204 (e.g., a silicon wafer or silicon-on-oxide wafer). Each recess 1202 has a substantially level and smooth bottom surface 1206, vertical sidewalls 1208, and a top opening 1210. The portions of the top surface of the semiconductor substrate surrounding the opening 1210 of the recess 1202 are planar and substantially parallel to the bottom surface 1206 of the recess 1202. In some implementations, the recesses 1202 are formed using a conventional Bosch process, and a mask layer 1212 (e.g., a silicon oxide layer) can remain on the planar portions of the substrate's top surface.

As shown in FIG. 12B, after the recesses 1202 with the flat bottom surfaces are formed in the semiconductor substrate 1204, an insulator coating 1214 is applied to the top surface of the semiconductor substrate 1204. The insulator coating 1214 covers the bottom surface 1206 as well as the side surfaces 1208 of the recesses 1202. In some implementations, the insulator coating 1214 is a thin layer (e.g., a few hundred angstroms) of oxide (e.g., SiO₂) deposited by PECVD. In some implementations, the insulator coating 1214 is a thin layer of oxide grown on the surface of the semiconductor substrate 1204 through thermal oxidation. As shown in FIG. 12B, the layer of insulator coating 1214 can also cover the planar portions of the substrate's top surface surrounding the openings 1210. The insulator coating 1214 has the ability to prevent plating metal ions from being reduced into plated metal by the free charges on the surface of the semiconductor substrate underneath the insulator coating 1214.

Once the insulator coating 1214 has been applied to the surface of the semiconductor substrate 1204 to cover the inner surfaces of the recesses 1202, the top surface of the coated semiconductor substrate 1204 can be exposed to dry etching from above. As shown in FIG. 12C, a dry etchant (e.g., a SF₆ gas) can be used to remove the insulator coating 1214 formed on the bottom surface 1206 of the recesses 1202. The etchant used in the dry etching processes are selected such that is has a much higher etch rate with respect to the material (e.g., Si) of the semiconductor substrate 1204, as compared to its etch rate with respect to the material (e.g., SiO₂) of the insulator coating 1214. As shown in FIG. 12C, due to the directionality (e.g., directed vertically at the bottom surface 1206) of the impinging etchant (e.g., SF₆), the center 1216 of the bottom surface 1206 becomes re-exposed first. After the center of the bottom surface 1206 becomes re-exposed (e.g., after a first time period), there is still insulator coating material remaining on the side surfaces 1208 of the recess 1202, and on the edge of the bottom surface 1206.

As shown in FIG. 12D, as the dry etching continues, the bottom surface 1206 of the recess 1202 is continually etched and expanded in the direction bending away from the top opening 1210 of the recess 1202. In contrast, the insulator coating 1214 formed on the side surfaces 1208 of the recess 1202 remain substantially intact, leaving the side surfaces 1208 protected from the etchant. The dry etching can be stopped after the insulator coating formed on the bottom surface is removed, e.g., after a second time period shorter than the first time period). As shown in FIG. 12D, after the dry etching, the bottom surface 1206 of the recess 1202 can include two planar facets 1218 that meet at an angle at the bottom center of the recess 1202. The overall surface area of the bottom surface 1206 has been significantly increased, as compared to the flat bottom surface of the recess 1202 shown in FIG. 12A.

As shown in FIG. 12E, when the semiconductor substrate 1204 is exposed to a plating environment containing plating metal ions (e.g., gold ions), the plating metal ions will form initial growth sites on the re-exposed and expanded bottom surface 1206 of the recess 1202. The plated metal 1220 will grow from the initial growth sites on the expanded bottom surface 1206 of the recess 1202 and gradually fill the recess 1202 from the bottom up. Since the side surfaces 1208 of the recesses 1202 are completely covered by the insulator coating 1214, the side surfaces 1208 will not compete with the bottom surface 1206 for the plating metal ions, and voids will not be formed along the length of the plated metal filled inside the recess 1202 (as shown in FIG. 12F).

The use of terminology such as “front,” “back,” “top,” “bottom,” “left,” “right,” “over,” “above,” and “below” throughout the specification and claims is for describing the relative positions of various components of the system(s) and relative positions of various parts of the various components described herein. Similarly, the use of any horizontal or vertical terms throughout the specification and claims is for describing the relative orientations of various components of the system(s) and the relative orientations of various parts of the various components described herein. Except where a relative orientation or position set forth below is explicitly stated in the description for a particular component, system, or device, the use of such terminology does not imply any particular positions or orientations of the system, device, component or part(s) thereof, relative to (1) the direction of the Earth's gravitational force, (2) the Earth ground surface or ground plane, (3) a direction that the system(s), device(s), or particular component(s) thereof may have in actual manufacturing, usage, or transportation; or (4) a surface that the system(s), device(s), or particular component(s) thereof may be disposed on during actual manufacturing, usage, or transportation.

A number of embodiments of the invention have been described. Nevertheless, it will be understood that various modifications may be made without departing from the spirit and scope of the inventions. For example, some processing steps may be carried out in a different order, modified, or omitted. The layout and configuration of the vibrating elements, electrodes, and electrical connections, may be varied.

What is claimed is:

1. A process, comprising:
forming a recess in a first surface of a semiconductor substrate,
wherein the recess has one or more side surfaces, a bottom surface and a top opening,
wherein the forming comprises creating surface profile characteristics on the bottom surface, the surface profile characteristics including an expanded surface area or a roughened surface texture that is operable to cause the bottom surface to provide a substantially more active plating area than the side surfaces do when the semiconductor substrate is exposed to plating metal ions in a plating environment; and
exposing the semiconductor substrate having the recess to the plating environment, where respective initial growth sites of a plated metallic conductor form on the bottom surface of the recess and the plated metallic conductor fills the recess starting from the bottom surface and then up along the side surfaces of the recess.

2. The process of claim 1, further comprising:
before exposing the semiconductor substrate to the plating environment,
applying an insulator coating on the first surface of the semiconductor substrate, the insulator coating partially covering the side surfaces of the recess, and leaving the bottom surface of the recess and bottom portions of the side surfaces adjacent to the bottom surface exposed.

3. The process of claim 1, wherein the surface profile characteristics of the bottom surface of the recess are produced by a plurality of silicon grass formed on the bottom surface of the recess.

4. The process of claim 1, wherein forming the one or more recesses further comprises:
etching the first surface of the semiconductor substrate using a first etching process, wherein the etching using the first etching process forms the one or more side surfaces of the recess, and the one or more side surfaces formed by the first etching process terminate at a substantially flat and smooth end surface, and
wherein creating the surface profile characteristics on the bottom surface further comprises:
after the etching using the first etching process is completed, dry etching the substantially flat and smooth end surface in the recess using a second etching process, wherein the second etching process causes a plurality of protrusions to form on the substantially flat end surface, and the end surface with the plurality of protrusions serves as the bottom surface of the recess.

5. The process of claim 4, wherein the first etching process is a Bosch process using a first etching recipe, the second etching process is a Bosch process using a second etching recipe, and the second etching recipe is operable to cause more particle deposition on the bottom surface of the recess than the first etching recipe does.

6. The process of claim 5, wherein the first etching recipe includes a first concentration of C₄F₈ gas in a respective passivation gas mixture used in a respective passivation cycle of the first etching process, the second etching recipe includes a second concentration of C₄F₈ gas in a respective passivation gas mixture used in a respective passivation cycle of the second etching process, and the second concentration is greater than the first concentration.

7. The process of claim 5, wherein the first etching recipe uses a first etching duration for a respective etching cycle of the first etching process, the second etching recipe uses a second etching duration for a respective etching cycle of the second etching process, and the second etching duration is shorter than the first etching duration.

8. The process of claim 5, wherein the first etching recipe uses a first passivation duration for a respective passivation cycle of the first etching process, the second etching recipe uses a second passivation duration for a respective passivation cycle of the second etching process, and the second passivation duration is longer than the first passivation duration.

9. The process of claim 1, wherein forming the recess in the first surface of the semiconductor substrate further comprises:
forming a mask layer on the first surface of the semiconductor substrate, the mask layer having an opening that define a location and lateral dimensions of the recess to be formed in the first surface of the semiconductor substrate;
anisotropically etching the first surface of the semiconductor substrate through the opening of the mask layer, the anisotropic etching forming a cavity in the first surface of the semiconductor substrate, an inner surface of cavity includes the surface profile characteristics of the bottom surface of the recess to be formed; and
after the cavity has been formed in the first surface of the semiconductor substrate, anisotropically etching the inner surface of the cavity in a direction perpendicular to the top opening of the recess to be formed in the first surface of the semiconductor substrate, the anisotropic etching of the inner surface of the cavity producing the side surfaces of the recess and the bottom surface of the recess having the surface profile characteristics.

10. The process of claim 9, wherein the semiconductor substrate is a silicon substrate, a top surface of the silicon substrate is aligned with the {100} crystal planes of the silicon substrate, wherein the recess is a linear recess having a length along the [011] direction of the silicon substrate.

11. The process of claim 1, wherein forming the recess in the first surface of the semiconductor substrate further comprises:
forming a photoresist layer on the first surface of the semiconductor substrate, the photoresist layer having a straight-walled opening that define a location and lateral dimensions of the recess to be formed in the first surface of the semiconductor substrate;
annealing the photoresist layer such that the straight-walled opening morphs to an opening having inwardly curving side walls;
etching the first surface of the semiconductor substrate through the opening having the inwardly curving side walls, the etching forming a cavity in the first surface of the semiconductor substrate, and an inner surface of cavity curving away from an opening of the cavity; and
after the cavity has been formed in the first surface of the semiconductor substrate, etching the semiconductor substrate through the inner surface of the cavity in a direction perpendicular to the top opening of the cavity, the etching through the inner surface of the cavity producing the side surfaces of the recess and the bottom surface of the recess curving away from the top opening of the recess, and the curved bottom surface provides the expanded surface area of the bottom surface.

12. The process of claim 1, wherein forming the recess in the first surface of the semiconductor substrate further comprises:
forming a photoresist layer on the first surface of the semiconductor substrate;
patterning the photoresist layer using a grayscale mask, the patterned photoresist layer having a thinner portion that define a location and lateral dimensions of the recess to be formed, and the thinner portion has thickness profile showing one or more protrusion above a baseline of the thinner portion;
etching the first surface of the semiconductor substrate through the patterned photoresist layer, the etching forming a cavity in the first surface of the semiconductor substrate, and an inner surface of cavity includes one or more protrusions matching the thickness profile of the patterned photoresist layer; and
after the cavity has been formed in the first surface of the semiconductor substrate, etching the semiconductor substrate through the inner surface of the cavity in a direction perpendicular to a top opening of the cavity, the etching through the inner surface of the cavity producing the side surfaces and the bottom surface of the recess, and bottom surface includes one or more protrusions that matching the one or more protrusions in the inner surface of the previously formed cavity.

13. The process of claim 1, wherein the recess has an aspect ratio in a range of 10:1 to 100:1 between a width of the bottom surface and a depth of the recess.

14. The process of claim 1, wherein the process forms a periodic array of recesses including the recess and fills each of the recesses with the plated metal conductor from the bottom up.

15. The process of claim 1, wherein the recess has a depth of 30-200 microns along the one or more side surfaces, a width of 2-20 microns along the bottom surface.

16. The process of claim 1, wherein the recess has a depth of approximately 100 microns, and a width of approximately 3 microns.

17. The process of claim 1, wherein the metallic conductor is gold.

18. The process of claim 1, wherein the semiconductor substrate comprises silicon.

19. The process of claim 1, wherein creating the surface profile characteristics comprises creating shards of silicon grass on the bottom surface of the recess.

20. The process of claim 1, wherein creating the surface profile characteristics comprises creating a plurality of protrusions on the bottom surface of the recess.

21. The process of claim 1, wherein creating the surface profile characteristics comprises creating a single pointy protrusion on the bottom surface of the recess.

22. The process of claim 1, wherein creating the surface profile characteristics comprises creating a bottom surface that bends away from the top opening of the recess.

23. The process of claim 22, wherein the bottom surface that bends away from the top opening of the recess includes two or more planar facets joining at an angle.

24. The process of claim 22, wherein the bottom surface that bends away from the top opening of the recess includes a smoothly curved surface that arches away from the top opening of the recess.

25. The process of claim 1, wherein at least a part of the side surfaces is coated by a dielectric material.

26. The process of claim 25, wherein the dielectric material is deposited by PECVD.

27. The process of claim 25, wherein the dielectric material is formed by thermal oxidization.

28. The process of claim 1, wherein creating the surface profile characteristics on the bottom surface further comprises:
applying an insulator coating on the first surface of the semiconductor substrate, the insulator coating covering the side surfaces and the bottom surface of the recess; and
etching portions of the insulator coating applied on the bottom surface of the recess using a dry etchant, wherein the dry etchant has a greater etch rate for the semiconductor substrate than the insulator coating, and wherein the etching leaves the side surfaces of the recess unexposed when the portions of the insulator coating applied on the bottom surface are completely removed by the dry etchant, and wherein the etching causes the bottom surface of the recess to bend away from the top opening of the recess.
